(19) United States
(12) Patent Application Publication
(10) Pub. No.: US 2024/0162923 A1
(43) Pub. Date: May 16, 2024

(54) RADIO FREQUENCY CIRCUIT AND COMMUNICATION DEVICE

(71) Applicant: Murata Manufacturing Co., Ltd., Nagaokakyo-shi (JP)

(72) Inventors: Kenji TAHARA, Nagaokakyo-shi (JP); Hiroki SHOUNAI, Nagaokakyo-shi (JP); Kae YAMAMOTO, Nagaokakyo-shi (JP); Ryo WAKABAYASHI, Nagaokakyo-shi (JP)

(73) Assignee: Murata Manufacturing Co., Ltd., Nagaokakyo-shi (JP)

(21) Appl. No.: 18/418,379

(22) Filed: Jan. 22, 2024

Related U.S. Application Data
(63) Continuation of application No. PCT/JP2022/028054, filed on Jul. 19, 2022.

(30) Foreign Application Priority Data
Jul. 28, 2021 (JP) 2021-123683

(51) Int. Cl. H04B 1/04; H04B 1/00

(52) U.S. Cl. CPC H04B 1/0458; H04B 1/0078; H04B 2001/0408

(57) ABSTRACT

A radio frequency circuit includes power amplifiers, a transformer, a filter having a band A as a pass band, a filter having a band B as a pass band, a filter having a band C as a pass band, matching circuits connected to one end of an output side coil, and matching circuits connected to the other end of the output side coil. The matching circuit includes a capacitor disposed at a first path, a switch connected to the first path and a ground, a switch and an inductor connected in series, and the matching circuit includes a capacitor disposed at a second path, and a switch and an inductor connected in series, and the matching circuit includes a switch connected to a third path and the ground.

### CROSS-REFERENCE TO RELATED APPLICATIONS

This is a continuation application of PCT/JP2022/028054, filed on Jul. 19, 2022, designating the United States of America, which is based on and claims priority to Japanese Patent Application No. JP 2021-123683 filed on Jul. 28, 2021. The entire contents of the above-identified applications, including the specifications, drawings and claims, are incorporated herein by reference in their entirety.

### TECHNICAL FIELD

The present disclosure relates to a radio frequency circuit and a communication device.

### BACKGROUND ART

Patent Document 1 discloses a power amplifier circuit that includes a first amplifier that amplifies a first signal distributed from an input signal in a region where a power level of the input signal is equal to or higher than a first level and outputs a second signal, a first transformer to which the second signal is input, a second amplifier that amplifies a third signal distributed from an input signal in a region where a power level of the input signal is higher than the first level and is equal to or higher than a second level and outputs a fourth signal, and a second transformer to which the fourth signal is input.

### CITATION LIST

### Patent Document

Patent Document 1: Japanese Unexamined Patent Application Publication No. 2018-137566

### SUMMARY OF DISCLOSURE

### Technical Problem

In the power amplifier circuit disclosed in Patent Document 1, in a case where radio frequency signals in a plurality of bands are amplified and individually transmitted, a plurality of filters that each have the plurality of bands as pass bands and a switch that switches between connection and non-connection between the power amplifier circuit and the plurality of filters are required on an output side of the power amplifier circuit.

However, when the switch is disposed on a signal path, a transmission loss of the radio frequency signal increases due to an on-resistance of the switch.

The present disclosure is made to solve the above problem, and an object thereof is to provide a radio frequency circuit having a plurality of amplification elements and a communication device that can transmit radio frequency signals in a plurality of bands with a low loss.

### Solution to Problem

In order to achieve the object, a radio frequency circuit according to one aspect of the present disclosure includes: a first amplification element and a second amplification element; a transformer having an input side coil and an output side coil; a first filter having a pass band including a first band; a second filter having a pass band including a second band; a third filter having a pass band including a third band; a first circuit connected between one end of the output side coil and the first filter; a second circuit connected between the one end of the output side coil and the second filter; and a third circuit connected between another end of the output side coil and the third filter. An output terminal of the first amplification element is connected to one end of the input side coil, and an output terminal of the second amplification element is connected to another end of the input side coil. The first circuit has a first capacitor disposed in series with a first path connecting the one end of the output side coil and the first filter, a first switch connected between the first path and a ground, and a second switch and a first inductor connected in series with each other. A series connection circuit of the second switch and the first inductor is connected in parallel to the first path. The second circuit has a second capacitor disposed in series with a second path connecting the one end of the output side coil and the second filter, and a third switch and a second inductor connected in series with each other. A series connection circuit of the third switch and the second inductor is connected in parallel to the second path, and the third circuit has a fourth switch connected between a ground and a third path connecting the other end of the output side coil and the third filter.

In addition, a radio frequency circuit according to another aspect of the present disclosure includes: a first amplification element, a second amplification element, a third amplification element, and a fourth amplification element; a first transformer having a first input side coil and a first output side coil; a second transformer having a second input side coil and a second output side coil; a first filter having a pass band including a first band; a second filter having a pass band including a second band; a third filter having a pass band including a third band; a fourth filter having a pass band including a fourth band; a first circuit connected between one end of the first output side coil and the first filter; a second circuit connected between the one end of the first output side coil and the second filter; a third circuit connected between one end of the second output side coil and the third filter; and a fourth circuit connected between the one end of the second output side coil and the fourth filter. An output terminal of the first amplification element is connected to one end of the first input side coil, an output terminal of the second amplification element is connected to another end of the first input side coil, an output terminal of the third amplification element is connected to one end of the second input side coil, an output terminal of the fourth amplification element is connected to another end of the second input side coil, and another end of the first output side coil is connected to another end of the second output side coil. The first circuit has a first capacitor disposed in series with a first path connecting the one end of the first output side coil and the first filter, a first switch connected between the first path and a ground, and a second switch and a first inductor connected in series with each other. A series connection circuit of the second switch and the first inductor is connected in parallel to the first path. The second circuit has a second capacitor disposed in series with a second path connecting the one end of the first output side coil and the second filter, a fifth switch connected between the second path and the ground, and a third switch and a second inductor connected in series with each other. A series connection circuit of the third switch and the second inductor is connected in parallel to the second path. The third circuit has a third capacitor disposed in series with a third path connecting the one end of the second output side coil and the third filter, a fourth switch connected between the third path and the ground, and a sixth switch and a third inductor connected in series with each other. A series connection circuit of the sixth switch and the third inductor is connected in parallel to the third path. The fourth circuit has a fourth capacitor disposed in series with a fourth path connecting the one end of the second output side coil and the fourth filter, a seventh switch connected between the fourth path and the ground, and an eighth switch and a fourth inductor connected in series with each other. A series connection circuit of the eighth switch and the fourth inductor is connected in parallel to the fourth path.

In addition, a radio frequency circuit according to still another aspect of the present disclosure includes: a first amplification element and a second amplification element; a first filter having a pass band including a first band; a first circuit connected between an output end of the first amplification element and one end of the first filter; and a second circuit connected between an input end of the second amplification element and the one end of the first filter. The first circuit has a first capacitor disposed in series with a first path connecting the output end of the first amplification element and the first filter, and a first series connection circuit that includes a first switch and a first inductor connected in series with each other, and is connected in parallel to the first capacitor. The second circuit has a second inductor disposed in series with a second path connecting the input end of the second amplification element and the first filter, and a second series connection circuit that includes a second switch and a second capacitor connected in series with each other, and is connected in parallel to the second inductor.

### Advantageous Effects of Disclosure

According to the present disclosure, it is possible to provide the radio frequency circuit having the plurality of amplification elements and the communication device, which can transmit the radio frequency signals in the plurality of bands with a low loss.

### BRIEF DESCRIPTION OF DRAWINGS

FIG. 1 is a circuit configuration diagram of a radio frequency circuit and a communication device according to an embodiment.

FIG. 2 is a diagram illustrating a combination of bands applied to the radio frequency circuit according to the embodiment.

FIG. 3A is a circuit state diagram of the radio frequency circuit according to the embodiment in a case where a signal in a band A is transmitted.

FIG. 3B is a graph showing bandpass characteristics of the radio frequency circuit according to the embodiment in a case where the signal in the band A is transmitted.

FIG. 4A is a circuit state diagram of the radio frequency circuit according to the embodiment in a case where a signal in a band B is transmitted.

FIG. 4B is a graph showing bandpass characteristics of the radio frequency circuit according to the embodiment in a case where the signal in the band B is transmitted.

FIG. 5A is a circuit state diagram of the radio frequency circuit according to the embodiment in a case where a signal in a band C is transmitted.

FIG. 5B is a graph showing bandpass characteristics of the radio frequency circuit according to the embodiment in a case where the signal in the band C is transmitted.

FIG. 6A is a circuit state diagram of the radio frequency circuit according to the embodiment in a case where a signal in a band D is transmitted.

FIG. 6B is a graph showing bandpass characteristics of the radio frequency circuit according to the embodiment in a case where the signal in the band D is transmitted.

FIG. 7 is a circuit configuration diagram of a radio frequency circuit according to Modification Example 1 of the embodiment.

FIG. 8 is a diagram illustrating a combination of bands applied to the radio frequency circuit according to Modification Example 1 of the embodiment.

FIG. 9 is a circuit configuration diagram of a radio frequency circuit according to Modification Example 2 of the embodiment.

FIG. 10 is a plan view and a cross-sectional view of a radio frequency circuit according to Example 1.

FIG. 11 is a plan view of a radio frequency circuit according to Example 2.

FIG. 12 is a circuit configuration diagram of a radio frequency circuit and a communication device according to Modification Example 3 of the embodiment.

FIG. 13A is a circuit state diagram of the radio frequency circuit according to Modification Example 3 in a case where the signal in the band A is transmitted.

FIG. 13B is a graph showing bandpass characteristics and impedance characteristics of a second circuit of the radio frequency circuit according to Modification Example 3 in a case where the signal in the band A is transmitted.

FIG. 14 is a circuit state diagram of the radio frequency circuit according to Modification Example 3 in a case where the signal in the band A is received.

FIG. 15A is a circuit state diagram of the radio frequency circuit according to Modification Example 3 in a case where the signal in the band A is transmitted and the signal in the band D is received.

FIG. 15B is a graph showing cross isolation characteristics of the radio frequency circuit according to Modification Example 3 in a case where the signal in the band A is transmitted and the signal in the band D is received.

### DESCRIPTION OF EMBODIMENTS

Hereinafter, embodiments of the present disclosure will be described in detail with reference to the accompanying drawings. Note that, the embodiments to be described below are all comprehensive or specific examples. Numerical values, shapes, materials, constituent elements, dispositions and connection forms of the constituent elements, and the like illustrated in the following embodiments are examples, and are not intended to limit the present disclosure.

Note that, each drawing is a schematic diagram in which emphasis, omission, or adjustment of a ratio is performed as appropriate to illustrate the present disclosure, and is not necessarily illustrated strictly, and may differ from an actual shape, positional relationship, and ratio. In each drawing, identical reference signs are assigned to substantially identical configurations, and redundant descriptions may be omitted or simplified.

In the present disclosure, “connected” is meant to include not only a case of being directly connected by a connection terminal and/or a wiring conductor but also a case of being electrically connected with another circuit element interposed therebetween. In addition, “connected between A and B” is meant as being connected to A and B on a path that connects A and B.

In addition, in the present disclosure, “signal path” means a transmission line including a wiring through which a radio frequency signal propagates, an electrode directly connected to the wiring, a terminal directly connected to the wiring or the electrode, and the like.

In the component disposition of the present disclosure, “plan view” means that an object is viewed by orthographic projection from a positive side of a z-axis onto an xy plane. “A overlaps B in plan view” means that a region of A orthogonally projected onto the xy plane overlaps a region of B orthogonally projected onto the xy plane. “A is disposed between B and C” means that at least one of a plurality of line segments connecting any point in B and any point in C passes through A. “A is disposed closer to C than B” means that a shortest distance between A and C is shorter than a shortest distance between B and C. In addition, a term indicating a relationship between elements such as “parallel” and “orthogonal”, a term indicating a shape of an element such as “rectangle”, and a numerical range do not represent only a strict meaning, but are also meant to include an error in a substantially equivalent range, for example, of about several %.

In addition, in the present disclosure, “a component A is disposed in series with a path B” means that both a signal input end and a signal output end of the component A are connected to a wiring, an electrode, or a terminal constituting the path B.

### EMBODIMENTS

[1. Circuit Configurations of Radio Frequency Circuit 1 and Communication Device 4]

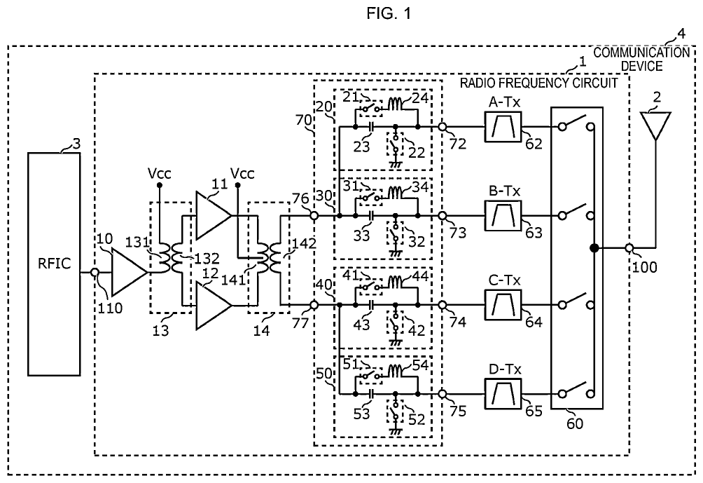

Circuit configurations of a radio frequency circuit 1 and a communication device 4 according to the present embodiment will be described with reference to FIG. 1. FIG. 1 is a circuit configuration diagram of the radio frequency circuit 1 and the communication device 4 according to the embodiment.

[1.1 Circuit Configuration of Communication Device 4]

First, the circuit configuration of the communication device 4 will be described. As illustrated in FIG. 1, the communication device 4 according to the present embodiment includes the radio frequency circuit 1, an antenna 2, and an RF signal processing circuit (RFIC) 3.

The radio frequency circuit 1 transmits a radio frequency signal between the antenna 2 and the RFIC 3. The detailed circuit configuration of the radio frequency circuit 1 will be described later.

In addition, the antenna 2 is connected to an antenna connection terminal 100 of the radio frequency circuit 1, transmits the radio frequency signal output from the radio frequency circuit 1, and receives a radio frequency signal from an outside and outputs the radio frequency signal to the radio frequency circuit 1.

The RFIC 3 is an example of a signal processing circuit that processes the radio frequency signal. Specifically, the RFIC 3 performs signal processing on a received signal input with a reception path of the radio frequency circuit 1 interposed therebetween by down-converting or the like, and outputs the received signal generated by the signal processing to a baseband signal processing circuit (BBIC, not illustrated). In addition, the RFIC 3 performs signal processing on a transmitted signal input from the BBIC by up-converting or the like, and outputs the transmitted signal generated by the signal processing to a transmission path of the radio frequency circuit 1. In addition, the RFIC 3 has a control unit that controls a switch, an amplification element, and the like of the radio frequency circuit 1. Note that, some or all of functions of the RFIC 3 as a control unit may be implemented outside the RFIC 3, for example, in the BBIC or the radio frequency circuit 1.

In addition, the RFIC 3 also has a function as a control unit that controls a power supply voltage Vcc and a bias voltage supplied to each amplifier of the radio frequency circuit 1. Specifically, the RFIC 3 outputs a digital control signal to the radio frequency circuit 1. The power supply voltage Vcc and the bias voltage controlled by the digital control signal are supplied to each amplifier of the radio frequency circuit 1.

In addition, the RFIC 3 also has a function as a control unit that controls the connection of each switch of the radio frequency circuit 1 based on a communication band (frequency band) to be used.

Note that, in the communication device 4 according to the present embodiment, the antenna 2 is not an essential constituent element.

[1.2 Circuit Configuration of Radio Frequency Circuit 1]

Next, the circuit configuration of the radio frequency circuit 1 will be described. As illustrated in FIG. 1, the radio frequency circuit 1 includes power amplifiers 11 and 12, a preamplifier 10, transformers 13 and 14, matching circuits 20, 30, 40, and 50, a switch 60, filters 62, 63, and 64 and 65, an input terminal 110, and the antenna connection terminal 100.

The input terminal 110 is connected to the RFIC 3, and the antenna connection terminal 100 is connected to the antenna 2.

Note that, each of the input terminal 110, the antenna connection terminal 100, and terminals 72 to 78 to be described later may be a metal conductor such as a metal electrode and a metal bump, or may be one point (node) on a metal wiring.

The preamplifier 10 amplifies radio frequency signals in bands A to D input from the input terminal 110.

The transformer 13 has a primary side coil 131 and a secondary side coil 132. One end of the primary side coil 131 is connected to a power supply (power supply voltage Vcc), and the other end of the primary side coil 131 is connected to an output terminal of the preamplifier 10. One end of the secondary side coil 132 is connected to an input terminal of the power amplifier 11, and the other end of the secondary side coil 132 is connected to an input terminal of the power amplifier 12. The transformer 13 distributes the radio frequency signal output from the preamplifier 10 into two radio frequency signals having a predetermined phase difference. Each of the two distributed radio frequency signals is input to the power amplifiers 11 and 12.

The power amplifier 11 is an example of a first amplification element, and has an amplification transistor. The power amplifier 12 is an example of a second amplification element, and has an amplification transistor. The amplification transistor is, for example, a bipolar transistor such as a heterojunction bipolar transistor (HBT) or a field effect transistor such as a metal-oxide-semiconductor field effect transistor (MOSFET).

The preamplifier 10, the power amplifiers 11 and 12, and the transformers 13 and 14 constitute a differential amplification type amplifier circuit. Note that, the preamplifier 10 and the transformer 13 are not included. In addition, the preamplifier 10, the power amplifiers 11 and 12, and the transformers 13 and 14 may constitute a Doherty amplifier circuit by the power amplifier 11 operating as a carrier amplifier and the power amplifier 12 operating as a peak amplifier. In this case, a phase shift circuit may be disposed instead of the transformer 13, and a phase shift line may be disposed at least between an output terminal of the power amplifier 11 and one end of an input side coil 141 or between an output terminal of the power amplifier 12 and the other end of an input side coil 141.

The transformer 14 has an input side coil 141 and an output side coil 142. One end of the input side coil 141 is connected to the output terminal of the power amplifier 11, and the other end of the input side coil 141 is connected to the output terminal of the power amplifier 12. A midpoint of the input side coil 141 is connected to the power supply (power supply voltage Vcc). One end of the output side coil 142 is connected to the matching circuits 20 and 30 through a terminal 76, and the other end of the output side coil 142 is connected to the matching circuits 40 and 50 through a terminal 77. The transformer 14 synthesizes the radio frequency signals output from the power amplifiers 11 and 12. The synthesized radio frequency signal is output to one of the terminals 76 and 77.

The filter 62 is an example of a first filter, and has a pass band that includes the band A (first band). An input end of the filter 62 is connected to the matching circuit 20 through the terminal 72.

The filter 63 is an example of a second filter, and has a pass band that includes the band B (second band). An input end of the filter 63 is connected to the matching circuit 30 through the terminal 73.

The filter 64 is an example of a third filter, and has a pass band that includes the band C (third band). An input end of the filter 64 is connected to the matching circuit 40 through a terminal 74.

The filter 65 is an example of a fourth filter, and has a pass band that includes the band D (fourth band). An input end of the filter 65 is connected to the matching circuit 50 through a terminal 75.

The switch 60 is an example of an antenna switch, and is connected to the antenna connection terminal 100. The switch 60 switches between connection and non-connection between the antenna connection terminal 100 and the filter 62, switches between connection and non-connection between the antenna connection terminal 100 and the filter 63, switches between connection and non-connection between the antenna connection terminal 100 and the filter 64, and switches between connection and non-connection between the antenna connection terminal 100 and the filter 65.

Note that, the filters 62 to 65 may constitute a multiplexer whose common terminal is connected to the antenna connection terminal 100, and in this case, the switch 60 is not included. In addition, in a case where each of the filters 62 to 65 is for a frequency division duplex (FDD), each filter may constitute a duplexer together with a receiving filter, and in a case where each filter is for a time division duplex (TDD), a switch that switches between transmission and reception may be disposed at least one of a front stage and a rear stage of each filter.

The matching circuit 20 is an example of a first circuit, and is connected between one end of the output side coil 142 and the filter 62. The matching circuit 20 has switches 21 and 22, a capacitor 23, and an inductor 24.

The capacitor 23 is an example of a first capacitor, and is disposed in series with a first path that connects one end of the output side coil 142 and the filter 62. The switch 22 is an example of a first switch, and is connected between the first path and a ground. The switch 21 is an example of a second switch, the inductor 24 is an example of a first inductor, and the switch 21 and the inductor 24 are connected in series with each other. A series connection circuit of the switch 21 and the inductor 24 is connected in parallel to the first path.

The matching circuit 30 is an example of a second circuit, and is connected between one end of the output side coil 142 and the filter 63. The matching circuit 30 has switches 31 and 32, a capacitor 33, and an inductor 34.

The capacitor 33 is an example of a second capacitor, and is disposed in series with a second path that connects one end of the output side coil 142 and the filter 63. The switch 32 is an example of a fifth switch, and is connected between the second path and the ground. The switch 31 is an example of a third switch, the inductor 34 is an example of a second inductor, and the switch 31 and the inductor 34 are connected in series with each other. A series connection circuit of the switch 31 and the inductor 34 is connected in parallel to the second path.

The matching circuit 40 is an example of a third circuit, and is connected between the other end of the output side coil 142 and the filter 64. The matching circuit 40 has switches 41 and 42, a capacitor 43, and an inductor 44.

The capacitor 43 is an example of a third capacitor, and is disposed in series with a third path that connects the other end of the output side coil 142 and the filter 64. The switch 42 is an example of a fourth switch, and is connected between the third path and the ground. The switch 41 is an example of a sixth switch, the inductor 44 is an example of a third inductor, and the switch 41 and the inductor 44 are connected in series with each other. A series connection circuit of the switch 41 and the inductor 44 is connected in parallel to the third path.

The matching circuit 50 is an example of a fourth circuit, and is connected between the other end of the output side coil 142 and the filter 65. The matching circuit 50 has switches 51 and 52, a capacitor 53, and an inductor 54.

The capacitor 53 is an example of a fourth capacitor, and is disposed in series with a fourth path that connects the other end of the output side coil 142 and the filter 65. The switch 52 is an example of a seventh switch, and is connected between the fourth path and the ground. The switch 51 is an example of an eighth switch, the inductor 54 is an example of a fourth inductor, and the switch 51 and the inductor 54 are connected in series with each other. A series connection circuit of the switch 51 and the inductor 54 is connected in parallel to the fourth path.

Note that, the matching circuits 20, 30, 40, and 50 may be included in an IC 70.

Note that, each of the switches 21, 22, 31, 32, 41, 42, 51, and 52 is a switch element including, for example, an FET or the like.

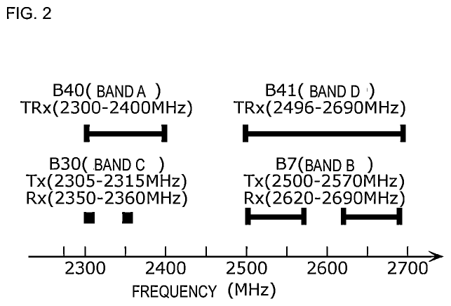

FIG. 2 is a diagram illustrating a combination of the bands applied to the radio frequency circuit 1 according to the embodiment. In the radio frequency circuit 1 according to the present embodiment, the band A is, for example, a band B40 (2300 to 2400 MHz) for time division duplex (TDD) and for 4th generation (4G)-long term evolution (LTE). In addition, the band B is, for example, a band B7 (uplink operating band: 2500 to 2570 MHz, downlink operating band: 2620 to 2690 MHz) for frequency division duplex (FDD) and for 4G-LTE. In addition, the band C is, for example, a band B30 (uplink operating band: 2305 to 2315 MHz, downlink operating band: 2350 to 2360 MHz) for FDD and for 4G-LTE. In addition, the band D is, for example, a band B41 (2496 to 2690 MHz) for TDD and for 4G-LTE.

Note that, each of the band A to the band D may be a band for 5th generation (5G)-New Radio (NR).

As illustrated in FIG. 2, the frequencies of the band A and the band B do not overlap each other, and the frequencies of the band C and the band D do not overlap each other. In addition, the frequencies of the band A and the band C overlap each other, and the frequencies of the band B and the band D overlap each other.

Note that, the frequencies of the band A and the band C do not overlap each other, and the frequencies of the band B and the band D do not overlap each other.

Note that, in the present embodiment, each of the band A to the band D means a frequency band defined in advance by a standardization organization (for example, 3GPP (registered trademark) (3rd Generation Partnership Project), the Institute of Electrical and Electronics Engineers (IEEE), or the like) for a communication system constructed by using radio access technology (RAT), and is not limited to the bands illustrated above. In the present embodiment, for example, a 4G-LTE system, a 5G-NR system, a wireless local area network (WLAN) system, and the like can be used as the communication system, but the present disclosure is not limited thereto.

According to the above circuit configuration, the radio frequency circuit 1 can transmit the radio frequency signal in any one of the band A to the band D from the input terminal 110 toward the antenna connection terminal 100. At this time, since the switch is not disposed in series with the first path of the matching circuit 20 that transmits the band A, the second path of the matching circuit 30 that transmits the band B, the third path of the matching circuit 40 that transmits the band C, and the fourth path of the matching circuit 50 that transmits the band D, the radio frequency signals in the band A to the band D can be transmitted with a low loss.

[1.3 Flow of Radio Frequency Signal in Radio Frequency Circuit 1]

Next, a flow of the radio frequency signals of the band A to the band D in the radio frequency circuit 1 will be described.

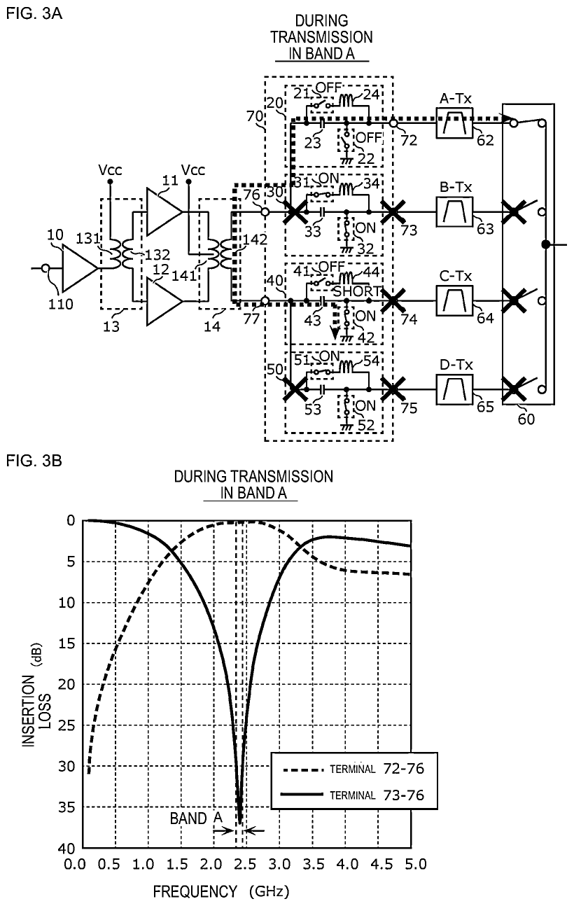

FIG. 3A is a circuit state diagram in a case where signals in the band A are transmitted by the radio frequency circuit 1 according to the embodiment. As illustrated in the drawing, in a case where the signals in the band A are transmitted, the switches 21 and 22 are in a non-conduction state, the switch 42 is in a conduction state, and the switch 41 is in a non-conduction state. It is necessary to bring the other end of the output side coil 142 into a short-circuit state in order to transmit the signals in the band A output from the power amplifiers 11 and 12 to the first path through the terminal 76. Since there is a connection wiring between the other end of the output side coil 142 and the switch 42, even though the vicinity of the switch 42 is short-circuited to the ground with the switch 42 in a conduction state, an impedance at the other end of the output side coil 142 is shifted from a short-circuit point by an inductance component of the connection wiring. In contrast, the impedance at the other end of the output side coil 142 shifted from the short-circuit point by the inductance component of the connection wiring can be brought into a short-circuit state by the capacitor 43 disposed in series between the switch 42 and the other end of the output side coil 142.

Note that, the capacitor 43, among the capacitor 43 and the switch 42, is desirably connected closer to the other end of the output side coil. As a result, the impedance at the other end of the output side coil 142 shifted from the short-circuit point by the inductance component of the connection wiring can be accurately brought into a short-circuit state.

In addition, the switches 31 and 32 of the matching circuit 30 are in a conduction state. As a result, in the matching circuit 30, a parallel connection circuit of the inductor 34 and the capacitor 33 is disposed between the terminal 76 and the ground.

FIG. 3B is a graph showing bandpass characteristics of the radio frequency circuit 1 according to the embodiment in a case where the signals in the band A are transmitted. In the drawing, bandpass characteristics (broken line) between the terminals 72 and 76 and bandpass characteristics (solid line) between the terminals 73 and 76 are illustrated.

The parallel connection circuit (LC resonance circuit) of the inductor 34 and the capacitor 33 functions as a band-elimination filter that does not pass the signal in the band A. That is, the matching circuit 30 is in an open state with respect to the signal in the band A by the switches 31 and 32 being in a conduction state.

As a result, as illustrated by the bandpass characteristics between the terminals 76 and 72, the signal in the band A can pass through the first path with a low loss.

Note that, in the matching circuit 50, the switches 51 and 52 may be in a conduction state. As a result, in the matching circuit 50, a parallel connection circuit of the inductor 54 and the capacitor 53 is disposed between the terminal 77 and the ground. As a result, the parallel connection circuit (LC resonance circuit) of the inductor 54 and the capacitor 53 can function as a band-elimination filter that does not pass the signal in the band A. That is, the matching circuit 50 is in an open state with respect to the signal in the band A by the switches 51 and 52 being in a conduction state.

By the above switch operation, the signals in the band A output from the power amplifiers 11 and 12 are transmitted from the first path to the filter 62 without passing through the switches disposed in series. Thus, the radio frequency circuit 1 can transmit the radio frequency signal in the band A with a low loss.

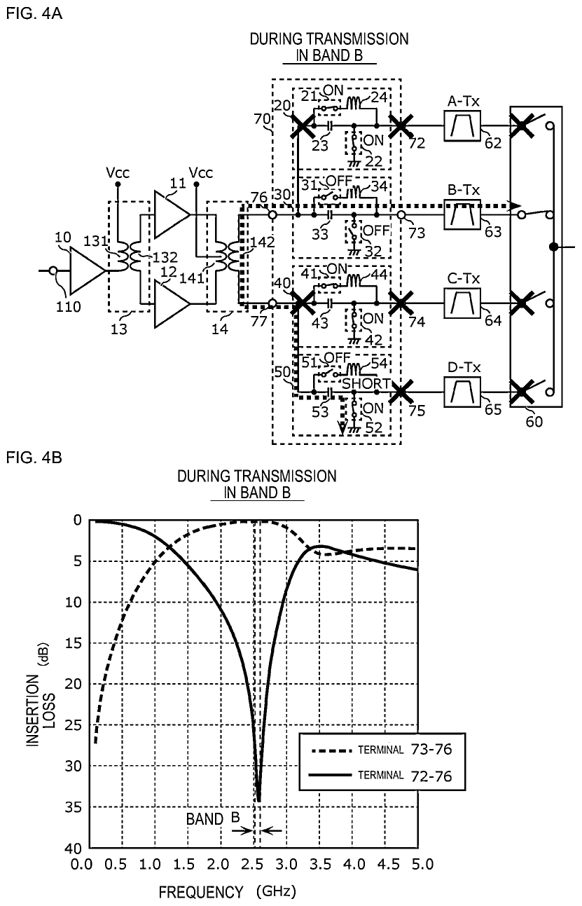

FIG. 4A is a circuit state diagram in a case where signals in the band B are transmitted by the radio frequency circuit 1 according to the embodiment. As illustrated in the drawing, in a case where the signals in the band B are transmitted, the switches 31 and 32 are in a non-conduction state, the switch 52 is in a conduction state, and the switch 51 is in a non-conduction state. It is necessary to bring the other end of the output side coil 142 into a short-circuit state in order to transmit the signals in the band B output from the power amplifiers 11 and 12 to the second path through the terminal 76. Since there is a connection wiring between the other end of the output side coil 142 and the switch 52, even though the vicinity of the switch 52 is short-circuited to the ground with the switch 52 in a conduction state, an impedance at the other end of the output side coil 142 is shifted from a short-circuit point by an inductance component of the connection wiring. In contrast, the impedance at the other end of the output side coil 142 shifted from the short-circuit point by the inductance component of the connection wiring can be brought into a short-circuit state by the capacitor 53 disposed in series between the switch 52 and the other end of the output side coil 142.

Note that, the capacitor 53, among the capacitor 53 and the switch 52, is desirably connected closer to the other end of the output side coil. As a result, the impedance at the other end of the output side coil 142 shifted from the short-circuit point by the inductance component of the connection wiring can be accurately brought into a short-circuit state.

In addition, the switches 21 and 22 of the matching circuit 20 are in a conduction state. As a result, in the matching circuit 20, a parallel connection circuit of the inductor 24 and the capacitor 23 is disposed between the terminal 76 and the ground.

FIG. 4B is a graph showing bandpass characteristics of the radio frequency circuit 1 according to the embodiment in a case where the signals in the band B are transmitted. In the drawing, the bandpass characteristics (broken line) between the terminals 73 and 76 and the bandpass characteristics (solid line) between the terminals 72 and 76 are illustrated.

The parallel connection circuit (LC resonance circuit) of the inductor 24 and the capacitor 23 functions as a band-elimination filter that does not pass the signal in the band B. That is, the matching circuit 20 is in an open state with respect to the signal in the band B by the switches 21 and 22 being in a conduction state.

As a result, as illustrated in the bandpass characteristics between the terminals 76 and 73, the signal in the band B can pass through the second path with a low loss.

Note that, in the matching circuit 40, the switches 41 and 42 may be in a conduction state. As a result, in the matching circuit 40, a parallel connection circuit of the inductor 44 and the capacitor 43 is disposed between the terminal 77 and the ground. As a result, the parallel connection circuit (LC resonance circuit) of the inductor 44 and the capacitor 43 can function as a band-elimination filter that does not pass the signal in the band B. That is, the matching circuit 40 is in an open state with respect to the signal in the band B by the switches 41 and 42 being in a conduction state.

By the above switch operation, the signals in the band B output from the power amplifiers 11 and 12 are transmitted from the second path to the filter 63 without passing through the switches disposed in series. Thus, the radio frequency circuit 1 can transmit the radio frequency signal in the band B with a low loss.

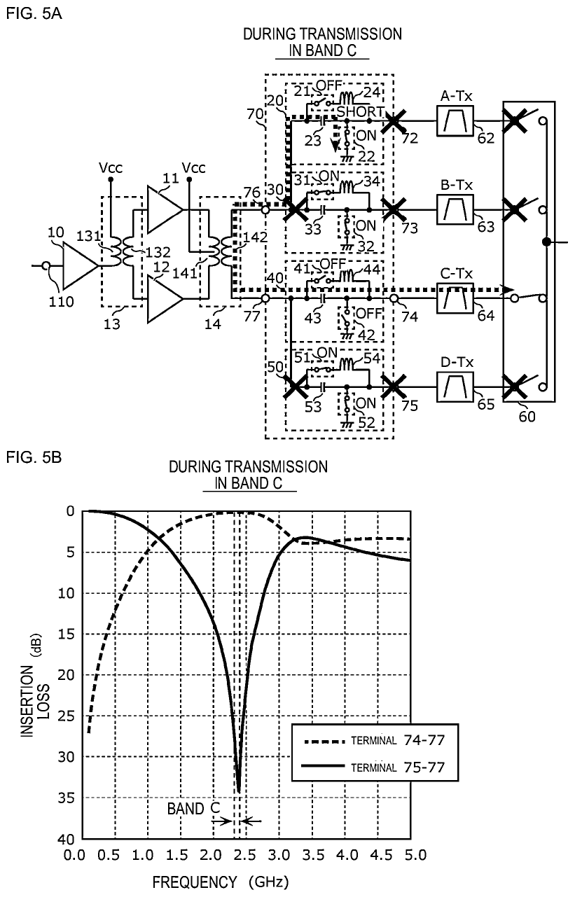

FIG. 5A is a circuit state diagram in a case where signals in the band C are transmitted by the radio frequency circuit 1 according to the embodiment. As illustrated in the drawing, in a case where the signals in the band C are transmitted, the switches 41 and 42 are in a non-conduction state, the switch 22 is in a conduction state, and the switch 21 is in a non-conduction state. It is necessary to bring one end of the output side coil 142 into a short-circuit state in order to transmit the signals in the band C output from the power amplifiers 11 and 12 to the third path through the terminal 77. Since there is a connection wiring between one end of the output side coil 142 and the switch 22, even though the vicinity of the switch 22 is short-circuited to the ground with the switch 22 in a conduction state, an impedance at one end of the output side coil 142 is shifted from a short-circuit point by an inductance component of the connection wiring. In contrast, the impedance at one end of the output side coil 142 shifted from the short-circuit point by the inductance component of the connection wiring can be brought into a short-circuit state by the capacitor 23 disposed in series between the switch 22 and one end of the output side coil 142.

Note that, the capacitor 23, among the capacitor 23 and the switch 22, is desirably connected closer to one end of the output side coil. As a result, the impedance at one end of the output side coil 142 shifted from the short-circuit point by the inductance component of the connection wiring can be accurately brought into a short-circuit state.

In addition, the switches 51 and 52 of the matching circuit 50 are in a conduction state. As a result, in the matching circuit 50, a parallel connection circuit of the inductor 54 and the capacitor 53 is disposed between the terminal 77 and the ground.

FIG. 5B is a graph showing bandpass characteristics of the radio frequency circuit 1 according to the embodiment in a case where the signals in the band C are transmitted. In the drawing, bandpass characteristics (broken line) between the terminals 74 and 77 and bandpass characteristic (solid line) between the terminals 75 and 77 are illustrated.

The parallel connection circuit (LC resonance circuit) of the inductor 54 and the capacitor 53 functions as a band-elimination filter that does not pass the signal in the band C. That is, the matching circuit 50 is in an open state with respect to the signal in the band C by the switches 51 and 52 being in a conduction state.

As a result, as illustrated in the bandpass characteristics between the terminals 77 and 74, the signal in the band C can pass through the third path with a low loss.

Note that, in the matching circuit 30, the switches 31 and 32 may be in a conduction state. As a result, in the matching circuit 30, a parallel connection circuit of the inductor 34 and the capacitor 33 is disposed between the terminal 76 and the ground. As a result, the parallel connection circuit (LC resonance circuit) of the inductor 34 and the capacitor 33 can function as a band-elimination filter that does not pass the signal in the band C. That is, the matching circuit 30 is in an open state with respect to the signal in the band C by the switches 31 and 32 being in a conduction state.

By the above switch operation, the signals in the band C output from the power amplifiers 11 and 12 are transmitted from the third path to the filter 64 without passing through the switches disposed in series. Thus, the radio frequency circuit 1 can transmit the radio frequency signal in the band C with a low loss.

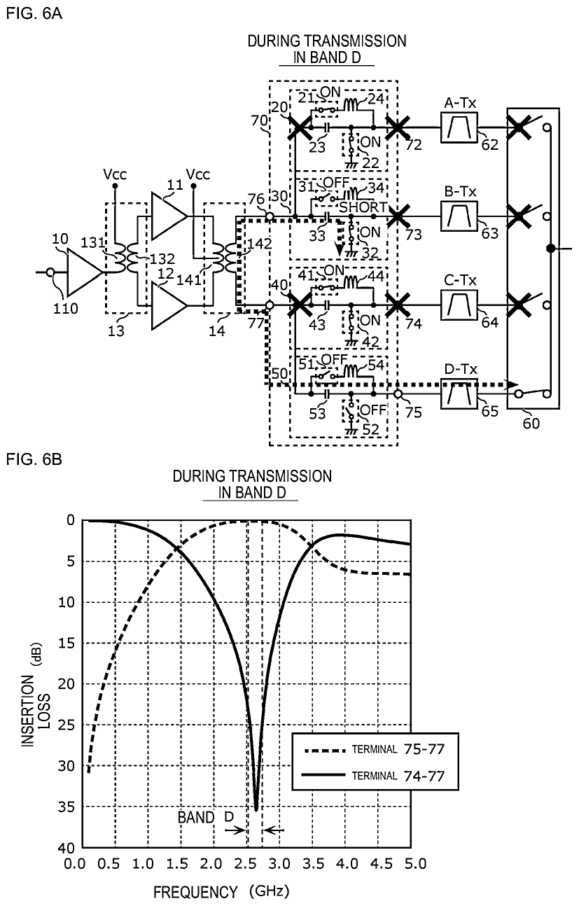

FIG. 6A is a circuit state diagram in a case where signals in the band D are transmitted by the radio frequency circuit 1 according to the embodiment. As illustrated in the drawing, in a case where the signals in the band D are transmitted, the switches 51 and 52 are in a non-conduction state, the switch 32 is in a conduction state, and the switch 31 is in a non-conduction state. It is necessary to bring one end of the output side coil 142 into a short-circuit state in order to transmit the signals in the band D output from the power amplifiers 11 and 12 to the fourth path through the terminal 77. Since there is a connection wiring between one end of the output side coil 142 and the switch 32, even though the vicinity of the switch 32 is short-circuited to the ground with the switch 32 in the conduction state, an impedance at one end of the output side coil 142 is shifted from a short-circuit point by an inductance component of the connection wiring. In contrast, the impedance at one end of the output side coil 142 shifted from the short-circuit point by the inductance component of the connection wiring can be brought into a short-circuit state by the capacitor 33 disposed in series between the switch 32 and one end of the output side coil 142.

Note that, the capacitor 33, among the capacitor 33 and the switch 32, is desirably connected closer to one end of the output side coil. As a result, the impedance at one end of the output side coil 142 shifted from the short-circuit point by the inductance component of the connection wiring can be accurately brought into a short-circuit state.

In addition, the switches 41 and 42 of the matching circuit 40 are in a conduction state. As a result, in the matching circuit 40, a parallel connection circuit of the inductor 44 and the capacitor 43 is disposed between the terminal 77 and the ground.

FIG. 6B is a graph showing bandpass characteristics of the radio frequency circuit 1 according to the embodiment in a case where the signals in the band D are transmitted. In the drawing, the bandpass characteristics (broken line) between the terminals 75 and 77 and the bandpass characteristics (solid line) between the terminals 74 and 77 are illustrated.

The parallel connection circuit (LC resonance circuit) of the inductor 44 and the capacitor 43 functions as a band-elimination filter that does not pass the signal in the band D. That is, the matching circuit 40 is in an open state with respect to the signal in the band D by the switches 41 and 42 being in a conduction state.

As a result, as illustrated in the bandpass characteristics between the terminals 77 and 75, the signal in the band D can pass through the fourth path with a low loss.

Note that, in the matching circuit 20, the switches 21 and 22 may be in a conduction state. As a result, in the matching circuit 20, a parallel connection circuit of the inductor 24 and the capacitor 23 is disposed between the terminal 76 and the ground. As a result, the parallel connection circuit (LC resonance circuit) of the inductor 24 and the capacitor 23 can function as a band-elimination filter that does not pass the signal in the band D. That is, the matching circuit 20 is in an open state with respect to the signal in the band D by the switches 21 and 22 being in a conduction state.

By the above switch operation, the signals in the band D output from the power amplifiers 11 and 12 are transmitted from the fourth path to the filter 65 without passing through the switches disposed in series. Thus, the radio frequency circuit 1 can transmit the radio frequency signal in the band D with a low loss.

Here, the capacitor 23 of the matching circuit 20 functions as an element for phase (impedance) adjustment at one end of the output side coil 142 in a case where the signals in the band C are transmitted, and functions as an element for the LC parallel resonance circuit for ensuring isolation between the first path and the second path in a case where the signals in the band B are transmitted. In addition, the capacitor 33 of the matching circuit 30 functions as an element for phase (impedance) adjustment at one end of the output side coil 142 in a case where the signals in the band D are transmitted, and functions as an element for the LC parallel resonance circuit for ensuring isolation between the first path and the second path in a case where the signals in the band A are transmitted. In addition, the capacitor 43 of the matching circuit 40 functions as an element for phase (impedance) adjustment at the other end of the output side coil 142 in a case where the signals in the band A are transmitted, and functions as an element for the LC parallel resonance circuit for ensuring isolation between the third path and the fourth path in a case where the signals in the band D are transmitted. In addition, the capacitor 53 of the matching circuit 50 functions as an element for phase (impedance) adjustment at the other end of the output side coil 142 in a case where the signals in the band B are transmitted, and functions as an element for the LC parallel resonance circuit for ensuring isolation between the third path and the fourth path in a case where the signals in the band C are transmitted.

In other words, since each of the capacitors 23, 33, 43, and 53 is a multifunctional element that also serves a plurality of functions, the number of circuit elements of the matching circuits 20 to 50 can be reduced. Thus, a size of the radio frequency circuit 1 is reduced.

In addition, for example, in the matching circuit 20, when an on-resistance of the switch 21 increases, a resistance component is superimposed on the LC parallel resonance circuit including the inductor 24 and the capacitor 23, and an attenuation of the band B as a band-elimination filter deteriorates. However, even in a case where the on-resistance of the switch 21 is large, the deterioration in the attenuation can be suppressed by setting an inductance value of the inductor 24 to be relatively large and a capacitance value of the capacitor 23 to be relatively small. That is, even in a case where the switch 21 does not have a low on-resistance, performance deterioration of the band B as a band-elimination filter can be suppressed by adjusting the inductance value of the inductor 24 and the capacitance value of the capacitor 23. Thus, since it is not necessary to use a high-performance switch having a low on-resistance and a capacitor having a large capacitance value, a size of the matching circuit 20 can be reduced.

Note that, sizes of the matching circuits 30, 40, and 50 can be similarly reduced from the above point of view.

[1.4 Circuit Configuration of Radio Frequency Circuit 1A According to Modification Example 1]

Although the radio frequency circuit 1 according to the embodiment has a configuration that can transmit signals in four different bands, a radio frequency circuit 1A according to the present modification example has a configuration that can transmit signals in three different bands.

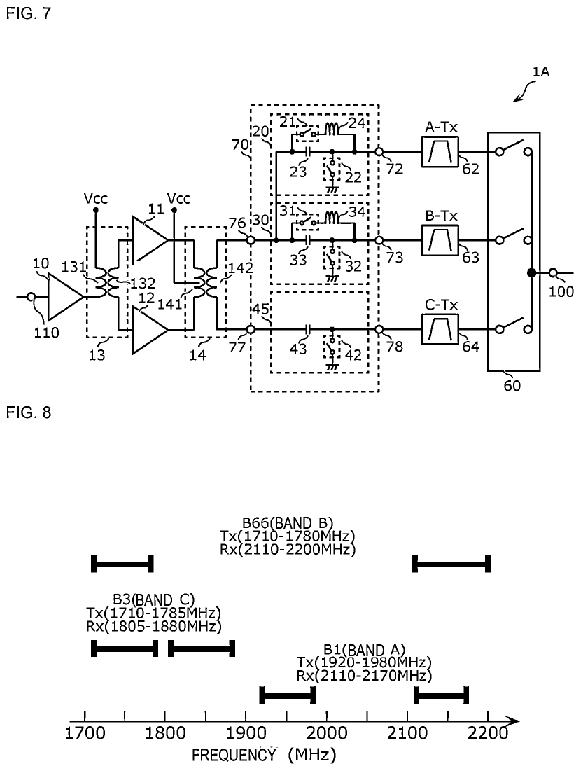

FIG. 7 is a circuit configuration diagram of the radio frequency circuit 1A according to Modification Example 1 of the embodiment. As illustrated in the drawing, the radio frequency circuit 1A includes power amplifiers 11 and 12, a preamplifier 10, transformers 13 and 14, matching circuits 20, 30, and 45, a switch 60, filters 62, 63, and 64, an input terminal 110 and an antenna connection terminal 100. The radio frequency circuit 1A according to the present modification example is different from the radio frequency circuit 1 according to the embodiment in that the matching circuit 50 and the filter 65 are not disposed and the matching circuit 45 is disposed instead of the matching circuit 40. Hereinafter, in the radio frequency circuit 1A according to the present modification example, the description of the same configuration as the radio frequency circuit 1 according to the embodiment will be omitted, and the description will be focused on different configurations.

The transformer 14 has an input side coil 141 and an output side coil 142. One end of the output side coil 142 is connected to the matching circuits 20 and 30 through a terminal 76, and the other end of the output side coil 142 is connected to the matching circuit 45 through a terminal 77.

The filter 64 is an example of a third filter, and has a pass band that includes the band C (third band). An input end of the filter 64 is connected to the matching circuit 45 through a terminal 78.

The switch 60 is an example of an antenna switch, and is connected to the antenna connection terminal 100. The switch 60 switches between connection and non-connection between the antenna connection terminal 100 and the filter 62, switches between connection and non-connection between the antenna connection terminal 100 and the filter 63, and switches between connection and non-connection between the antenna connection terminal 100 and the filter 64.

The matching circuit 45 is an example of a third circuit, and is connected between the other end of the output side coil 142 and the filter 64. The matching circuit 45 has a switch 42 and a capacitor 43.

The capacitor 43 is an example of a third capacitor, and is disposed in series with a third path that connects the other end of the output side coil 142 and the filter 64. The switch 42 is an example of a fourth switch, and is connected between the third path and the ground.

FIG. 8 is a diagram illustrating a combination of bands applied to the radio frequency circuit 1A according to Modification Example 1 of the embodiment. In the radio frequency circuit 1A according to the present modification example, a band A is, for example, a band B1 (uplink operating band: 1920 to 1980 MHz, downlink operating band: 2110 to 2170 MHz) for FDD and for 4G-LTE. In addition, a band B is, for example, a band B66 (uplink operating band: 1710 to 1780 MHz, downlink operating band: 2110 to 2200 MHz) for FDD and for 4G-LTE. In addition, a band C is, for example, a band B3 (uplink operating band: 1710 to 1785 MHz, downlink operating band: 1805 to 1880 MHz) for FDD and for 4G-LTE.

Note that, each of the band A to the band C may be a band for 5G-NR.

As illustrated in FIG. 8, the frequencies of the uplink operating band of the band A and the uplink operating band of the band B do not overlap each other, and the frequencies of the uplink operating band of the band B and the uplink operating band of the band C overlap each other.

Note that, the frequencies of the uplink operating band of the band B and the uplink operating band of the band C do not overlap each other.

According to the above circuit configuration, the radio frequency circuit 1A can transmit any radio frequency signal in the band A to the band C from the input terminal 110 toward the antenna connection terminal 100. At this time, since the switch is not disposed in series with a first path of the matching circuit 20 that transmits the band A, a second path of the matching circuit 30 that transmits the band B, and a third path of the matching circuit 45 that transmits the band C, the radio frequency signals in the band A to the band C can be transmitted with a low loss.

[1.5 Flow of Radio Frequency Signal in Radio Frequency Circuit 1A]

Next, a flow of the radio frequency signals in the band A to the band C in the radio frequency circuit 1A will be described.

First, in a case where signals in the band A are transmitted, the switches 21 and 22 are in a non-conduction state, and the switch 42 is in a conduction state. It is necessary to bring the other end of the output side coil 142 into a short-circuit state in order to transmit the signals in the band A output from the power amplifiers 11 and 12 to the first path through the terminal 76. Since there is a connection wiring between the other end of the output side coil 142 and the switch 42, even though the vicinity of the switch 42 is short-circuited to the ground with the switch 42 in a conduction state, an impedance at the other end of the output side coil 142 is shifted from a short-circuit point by an inductance component of the connection wiring. In contrast, the impedance at the other end of the output side coil 142 shifted from the short-circuit point by the inductance component of the connection wiring can be brought into a short-circuit state by the capacitor 43 disposed in series between the switch 42 and the other end of the output side coil 142.

Note that, the capacitor 43, among the capacitor 43 and the switch 42, is desirably connected closer to the other end of the output side coil. As a result, the impedance at the other end of the output side coil 142 shifted from the short-circuit point by the inductance component of the connection wiring can be accurately brought into a short-circuit state.

In addition, the switches 31 and 32 of the matching circuit 30 are in a conduction state. As a result, in the matching circuit 30, a parallel connection circuit of the inductor 34 and the capacitor 33 is disposed between the terminal 76 and the ground. The parallel connection circuit of the inductor 34 and the capacitor 33 functions as a band-elimination filter that does not pass the signal in the band A. That is, the matching circuit 30 is in an open state with respect to the signal in the band A by the switches 31 and 32 being in a conduction state. As a result, the signal in the band A can pass through the first path with a low loss.

Subsequently, in a case where signals in the band B are transmitted, the switches 31 and 32 are in a non-conduction state, and the switch 42 is in a conduction state. It is necessary to bring the other end of the output side coil 142 into a short-circuit state in order to transmit the signals in the band B output from the power amplifiers 11 and 12 to the second path through the terminal 76. In contrast, the impedance at the other end of the output side coil 142 shifted from the short-circuit point by the inductance component of the connection wiring between the other end of the output side coil 142 and the switch 42 can be brought into a short-circuit state by the capacitor 43 disposed in series between the switch 42 and the other end of the output side coil 142.

In addition, the switches 21 and 22 of the matching circuit 20 are in a conduction state. As a result, in the matching circuit 20, a parallel connection circuit of the inductor 24 and the capacitor 23 is disposed between the terminal 76 and the ground. The parallel connection circuit of the inductor 24 and the capacitor 23 functions as a band-elimination filter that does not pass the signal in the band B. That is, the matching circuit 20 is in an open state with respect to the signal in the band B by the switches 21 and 22 being in a conduction state. As a result, the signal in the band B can pass through the second path with a low loss.

Subsequently, in a case where signals in the band C are transmitted, the switch 42 is a non-conduction state, and the switch 22 is in a conduction state. It is necessary to bring one end of the output side coil 142 into a short-circuit state in order to transmit the signals in the band C output from the power amplifiers 11 and 12 to the third path through the terminal 77. In contrast, the impedance at one end of the output side coil 142 shifted from the short-circuit point by the inductance component of the connection wiring between one end of the output side coil 142 and the switch 22 can be brought into a short-circuit state by the capacitor 23 disposed in series between the switch 22 and one end of the output side coil 142.

Note that, the capacitor 23, among the capacitor 23 and the switch 22, is desirably connected closer to one end of the output side coil. As a result, the impedance at one end of the output side coil 142 shifted from the short-circuit point by the inductance component of the connection wiring can be accurately brought into a short-circuit state.

In addition, the switches 31 and 32 of the matching circuit 30 are in a conduction state. As a result, in the matching circuit 30, a parallel connection circuit of the inductor 34 and the capacitor 33 is disposed between the terminal 76 and the ground. The parallel connection circuit of the inductor 34 and the capacitor 33 functions as a band-elimination filter that does not pass the signal in the band C. That is, the matching circuit 30 is in an open state with respect to the signal in the band C by the switches 31 and 32 being in a conduction state. As a result, the signal in the band C can pass through the third path with a low loss.

Note that, the switch 32 and the capacitor 43 are not included in the radio frequency circuit 1A according to the present modification example. However, in this case, a case where the switch 42 is disposed close to the other end of the output side coil 142 and a case where the frequencies of the band A and the band B do not overlap each other and a frequency interval is sufficiently ensured are required. An operation of the circuit configuration will be described below.

First, in a case where signals in the band A are transmitted, the switches 21 and 22 are in a non-conduction state, and the switch 42 is in a conduction state. As a result, the impedance at the other end of the output side coil 142 can be brought into a short-circuit state.

In addition, the switch 31 of the matching circuit 30 is in a conduction state. As a result, in the matching circuit 30, the parallel connection circuit of the inductor 34 and the capacitor 33 is disposed between the terminal 76 and the terminal 73. The parallel connection circuit of the inductor 34 and the capacitor 33 functions as a filter that does not pass the signal in the band A. That is, the matching circuit 30 is in an open state with respect to the signal in the band A by the switch 31 being in a conduction state. As a result, the signal in the band A can pass through the first path with a low loss.

Subsequently, in a case where the signals in the band B are transmitted, the switch 31 is in a non-conduction state, and the switch 42 is in a conduction state. As a result, the impedance at the other end of the output side coil 142 can be brought into a short-circuit state.

In addition, the switches 21 and 22 of the matching circuit 20 are in a conduction state. As a result, in the matching circuit 20, a parallel connection circuit of the inductor 24 and the capacitor 23 is disposed between the terminal 76 and the ground. The parallel connection circuit of the inductor 24 and the capacitor 23 functions as a band-elimination filter that does not pass the signal in the band B. That is, the matching circuit 20 is in an open state with respect to the signal in the band B by the switches 21 and 22 being in a conduction state. As a result, the signal in the band B can pass through the second path with a low loss.

Subsequently, in a case where signals in the band C are transmitted, the switch 42 is a non-conduction state, and the switch 22 is in a conduction state. It is necessary to bring one end of the output side coil 142 into a short-circuit state in order to transmit the signals in the band C output from the power amplifiers 11 and 12 to the third path through the terminal 77. In contrast, the impedance at one end of the output side coil 142 shifted from the short-circuit point by the inductance component of the connection wiring between one end of the output side coil 142 and the switch 22 can be brought into a short-circuit state by the capacitor 23 disposed in series between the switch 22 and one end of the output side coil 142.

By the above operation, the signal in the band A can pass through the first path with a low loss, the signal in the band B can pass through the second path with a low loss, and the signal in the band C can pass through the third path with a low loss.

As a result, a radio frequency circuit having a plurality of amplification elements and transformers, which can transmit radio frequency signals in a plurality of bands A to C with a low loss, can be provided.

[1.6 Circuit Configuration of Radio Frequency Circuit 1B According to Modification Example 2]

Although the radio frequency circuit 1 according to the embodiment has an amplifier circuit having two power amplifiers and one output transformer, a radio frequency circuit 1B according to the present modification example has an amplifier circuit having four power amplifiers and two output transformers.

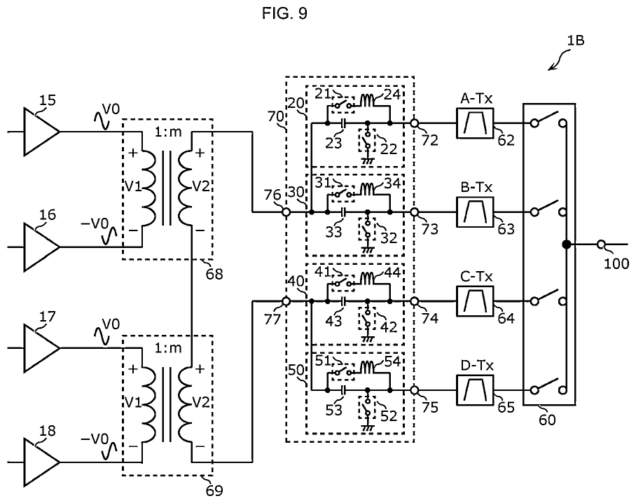

FIG. 9 is a circuit configuration diagram of the radio frequency circuit 1B according to Modification Example 2 of the embodiment. As illustrated in the drawing, the radio frequency circuit 1B includes power amplifiers 15, 16, 17 and 18, transformers 68 and 69, matching circuits 20, 30, 40, and 50, a switch 60, filters 62, 63, 64, and 65, and an antenna connection terminal 100. The radio frequency circuit 1B according to the present modification example is different from the radio frequency circuit 1 according to the embodiment in that four power amplifiers 15 to 18 and two transformers 68 and 69 are disposed. Hereinafter, in the radio frequency circuit 1B according to the present modification example, the description of the same configuration as the radio frequency circuit 1 according to the embodiment will be omitted, and the description will be focused on different configurations.

The power amplifier 15 is an example of a first amplification element, and has an amplification transistor. The power amplifier 16 is an example of a second amplification element, and has an amplification transistor. The power amplifier 17 is an example of a third amplification element, and has an amplification transistor. The power amplifier 18 is an example of a fourth amplification element, and has an amplification transistor. The amplification transistor is, for example, a bipolar transistor such as HBT or a field effect transistor such as MOSFET.

The power amplifiers 15 and 16 and the transformer 68 constitute a differential amplification type amplifier circuit. In addition, the power amplifiers 17 and 18 and the transformer 69 constitute a differential amplification type amplifier circuit. Note that, a preamplifier and an inter-stage transformer may be disposed in a front stage of the power amplifiers 15 to 18. In addition, a Doherty amplifier circuit may be constituted by the power amplifier 15 operating as a carrier amplifier and the power amplifier 16 operating as a peak amplifier. In addition, a Doherty amplifier circuit may be constituted by the power amplifier 17 operating as a carrier amplifier and the power amplifier 18 operating as a peak amplifier. In this case, a phase shift line may be disposed at least between an output terminal of the power amplifier 15 and one end of an input side coil of the transformer 68 or between an output terminal of the power amplifier 16 and the other end of the input side coil of the transformer 68. In addition, a phase shift line may be disposed at least between an output terminal of the power amplifier 17 and one end of an input side coil of the transformer 69 or between an output terminal of the power amplifier 18 and the other end of an input side coil of the transformer 69.

The transformer 68 is an example of a first transformer, and has a first input side coil and a first output side coil. One end of the first input side coil is connected to the output terminal of the power amplifier 15, and the other end of the first input side coil is connected to the output terminal of the power amplifier 16. One end of the first output side coil is connected to the matching circuits 20 and 30 through a terminal 76, and the other end of the first output side coil is connected to the other end of the second output side coil of the transformer 69. The transformer 68 synthesizes the radio frequency signals output from the power amplifiers 15 and 16. The synthesized radio frequency signal is output to one of the terminals 76 and 77.

The transformer 69 is an example of a second transformer, and has a second input side coil and a second output side coil. One end of the second input side coil is connected to the output terminal of the power amplifier 17, and the other end of the second input side coil is connected to the output terminal of the power amplifier 18. One end of the second output side coil is connected to the matching circuits 40 and 50 through the terminal 77, and the other end of the second output side coil is connected to the other end of the first output side coil of the transformer 68. The transformer 69 synthesizes the radio frequency signals output from the power amplifiers 17 and 18. The synthesized radio frequency signal is output to one of the terminals 76 and 77.

The matching circuit 20 is an example of a first circuit, and is connected between one end of the first output side coil and the filter 62.

The matching circuit 30 is an example of a second circuit, and is connected between one end of the first output side coil and the filter 63.

The matching circuit 40 is an example of a third circuit, and is connected between one end of the second output side coil and the filter 64.

The matching circuit 50 is an example of a fourth circuit, and is connected between one end of the second output side coil and the filter 64.

Note that, an operation of each switch included in the matching circuits 20 to 50 is similar to the radio frequency circuit 1 according to the embodiment. As a result, the signals in the band A output from the power amplifiers 15 to 18 are transmitted from the first path to the filter 62 without passing through the switches disposed in series. In addition, the signals in the band B output from the power amplifiers 15 to 18 are transmitted from the second path to the filter 63 without passing through the switches disposed in series. In addition, the signals in the band C output from the power amplifiers 15 to 18 are transmitted from the third path to the filter 64 without passing through the switches disposed in series. In addition, the signals in the band D output from the power amplifiers 15 to 18 are transmitted from the fourth path to the filter 65 without passing through the switches disposed in series. Thus, the radio frequency circuit 1B can transmit the radio frequency signals in the band A to the band D with a low loss.

[1.7 Implementation Configuration of Radio Frequency Circuit 1]

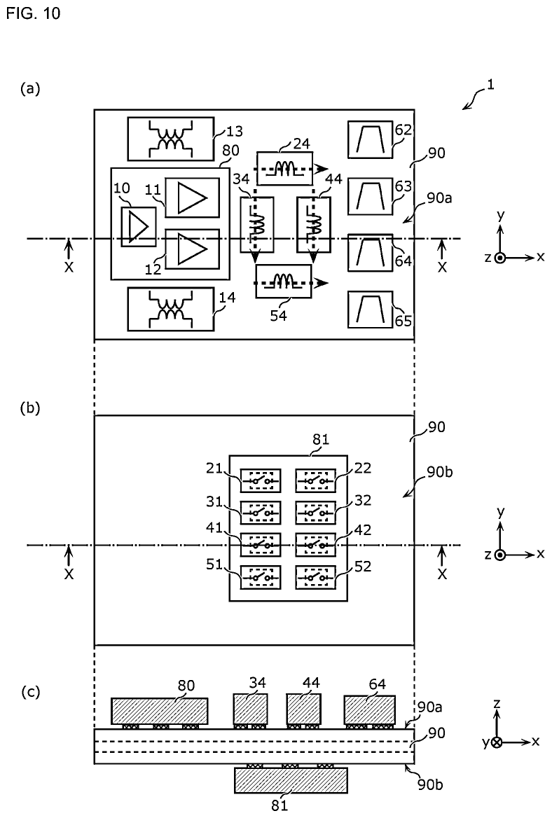

An implementation configuration of the radio frequency circuit 1 according to the present embodiment will be described with reference to FIG. 10.

FIG. 10 is a plan view and a cross-sectional view of a radio frequency circuit 1 according to Example 1. (a) of FIG. 10 is a see-through view of a principal surface 90a side of a module board 90 from the positive side of the z-axis, and (b) of FIG. 10 is a see-through view of a principal surface 90b side of the module board 90 from the positive side of the z-axis. (c) of FIG. 10 is a cross-sectional view of the radio frequency circuit 1 according to the example. A cross section of the radio frequency circuit 1 in (c) of FIG. 10 is a cross section taken along line X-X in (a) and (b) of FIG. 10.

Note that, in FIG. 10, although a symbol indicating each component may be assigned to each component such that a disposition relationship between the components is easily understood, the symbol is not assigned to each actual component. In addition, in FIG. 10, a part of a wiring that connects a plurality of electronic components disposed at the module board 90 is not illustrated. In addition, in FIG. 10, a resin member that covers a plurality of electronic components and a shield electrode layer that covers a surface of the resin member are not illustrated.

The radio frequency circuit 1 includes the module board 90 in addition to the plurality of electronic components including the plurality of circuit elements included in the radio frequency circuit 1 illustrated in FIG. 1.

The module board 90 has the principal surfaces 90a and 90b facing each other. The principal surfaces 90a and 90b are examples of a first principal surface and a second principal surface, respectively. Note that, in FIG. 10, the module board 90 has a rectangular shape in plan view, but the present disclosure is not limited to the shape.

For example, a low temperature co-fired ceramic (LTCC) board having a stacked structure of a plurality of dielectric layers or a high temperature co-fired ceramic (HTCC) board, a component built-in board, a board having a redistribution layer (RDL), a printed board, or the like can be used as the module board 90, but the present disclosure is not limited thereto.

On the principal surface 90a, the power amplifiers 11 and 12, the preamplifier 10, the transformers 13 and 14, the inductors 24, 34, 44 and 54, and the filters 62, 63, 64 and 65 are disposed.

The switches 21, 22, 31, 32, 41, 42, 51, and 52 are disposed on the principal surface 90b.

The preamplifier 10 and the power amplifiers 11 and 12 constitute a semiconductor IC 80.

The switches 21, 22, 31, 32, 41, 42, 51, and 52 constitute a semiconductor IC 81. Each of the semiconductor ICs 80 and 81 is made of, for example, at least one of gallium arsenic (GaAs), silicon germanium (SiGe), and gallium nitride (GaN). Note that, the semiconductor ICs 80 and 81 may be a complementary metal oxide semiconductor (CMOS), and specifically may be manufactured by a silicon on insulator (SOI) process. Note that, semiconductor materials of the semiconductor ICs 80 and 81 are not limited to the above-described materials.

Note that, the switch 60 and the capacitors 23, 33, 43, and 53 are not illustrated in FIG. 10, but may be disposed either on the principal surfaces 90a and 90b or an inside of the module board 90. In addition, the transformers 13 and 14 may be disposed on the principal surface 90b or the inside of the module board 90.

According to the above configuration, since the circuit components constituting the radio frequency circuit 1 are disposed on the principal surfaces 90a and 90b in a distribution manner, the size of the radio frequency circuit 1 can be reduced.

Here, in a case where the module board 90 is viewed in plan view, the inductors 24, 34, 44, and 54 and the semiconductor IC 81 at least partially overlap each other.

Accordingly, the wiring that connects the inductor 24 and the switches 21 and 22 in the matching circuit 20 can be shortened. In addition, in the matching circuit 30, the wiring that connects the inductor 34 and the switches 31 and 32 can be shortened. In addition, in the matching circuit 40, the wiring that connects the inductor 44 and the switches 41 and 42 can be shortened. In addition, in the matching circuit 50, the wiring that connects the inductor 54 and the switches 51 and 52 can be shortened. Thus, the size and the loss of the radio frequency circuit 1 can be reduced.

In addition, a magnetic flux direction of the inductor 24 and a magnetic flux direction of the inductor 44 are orthogonal to each other, and a magnetic flux direction of the inductor 34 and a magnetic flux direction of the inductor 54 are orthogonal to each other. As a result, even in a case where the frequencies of the band A and the band C partially overlap or are close to each other, signal leakage through magnetic coupling of the inductors 24 and 44 can be suppressed. In addition, even in a case where the frequencies of the band B and the band D partially overlap or are close to each other, signal leakage through magnetic coupling of the inductors 34 and 54 can be suppressed.

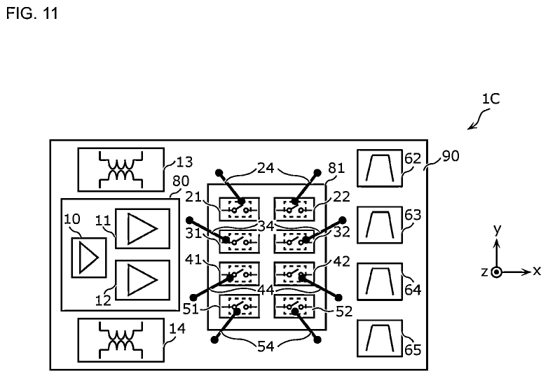

FIG. 11 is a plan view of a radio frequency circuit 1C according to Example 2. FIG. 11 is a see-through view of the principal surface of the module board 90 from the positive side of the z-axis.

Note that, in FIG. 11, although a symbol indicating each component may be assigned to each component such that a disposition relationship between the components is easily understood, the symbol is not assigned to each actual component. In addition, in FIG. 11, a part of a wiring that connects a plurality of electronic components disposed at the module board 90 is not illustrated. In addition, in FIG. 11, a resin member that covers a plurality of electronic components and a shield electrode layer that covers a surface of the resin member are not illustrated.

The radio frequency circuit 1C includes the module board 90 in addition to the plurality of electronic components including the plurality of circuit elements included in the radio frequency circuit 1 illustrated in FIG. 1.

The power amplifiers 11 and 12, the preamplifier 10, the transformers 13 and 14, the inductors 24, 34, 44, and 54, the filters 62, 63, 64, and 65, the switches 21, 22, 31, 32, 41, 42, 51, and 52 are disposed on the principal surface of the module board 90.

The preamplifier 10 and the power amplifiers 11 and 12 constitute a semiconductor IC 80.

The switches 21, 22, 31, 32, 41, 42, 51, and 52 constitute a semiconductor IC 81.

Note that, the switch 60 and the capacitors 23, 33, 43, and 53 are not illustrated in FIG. 11, but may be disposed either on the principal surface of the module board 90 or the inside of the module board 90. In addition, the transformers 13 and 14 may be disposed on the inside of the module board 90.

Here, each of the inductors 24, 34, 44, and 54 is formed by using a bonding wire. Accordingly, a degree of freedom in disposing the inductors 24, 34, 44, and 54 is ensured, and the size of the radio frequency circuit 1C can be reduced.

[1.8 Circuit Configuration of Radio Frequency Circuit 1D According to Modification Example 3]

Although the radio frequency circuit 1 according to the embodiment has an amplifier circuit having two power amplifiers and one output transformer, a radio frequency circuit 1D according to the present modification example includes a power amplifier and a low noise amplifier.

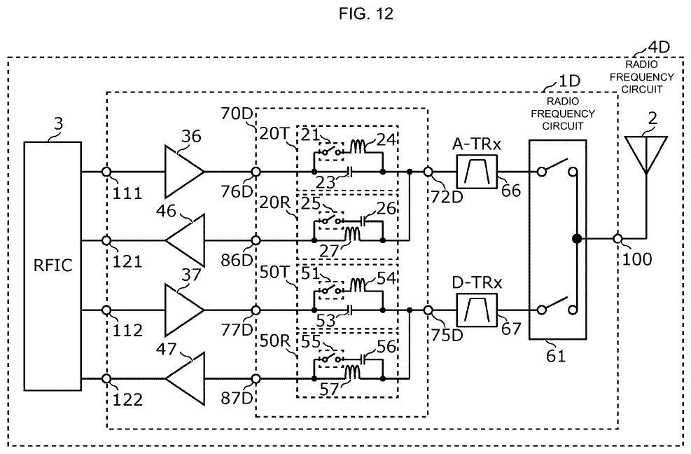

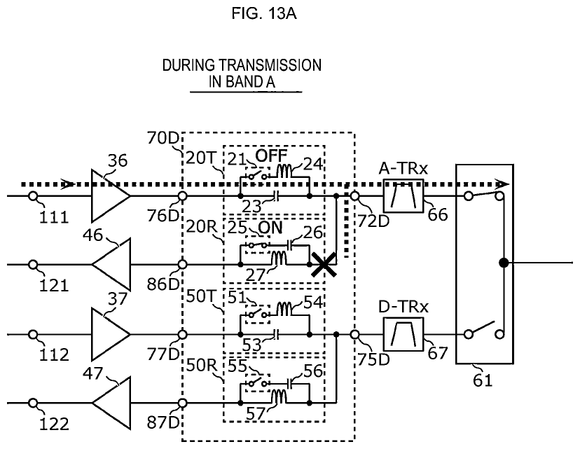

FIG. 12 is a circuit configuration diagram of the radio frequency circuit 1D and a communication device 4D according to Modification Example 3 of the embodiment. The communication device 4D includes the radio frequency circuit 1D, an antenna 2, and an RFIC 3. The communication device 4D according to the present modification example is different in the configuration of the radio frequency circuit 1D, as compared with the radio frequency circuit 1 according to the embodiment. Thus, hereinafter, in the communication device 4D according to the present modification example, the configuration of the radio frequency circuit 1D will be described.

As illustrated in FIG. 12, the radio frequency circuit 1D includes power amplifiers 36 and 37, low noise amplifiers 46 and 47, matching circuits 20T, 20R, 50T, and 50R, a switch 61, filters 66 and 67, input terminals 111 and 112, output terminals 121 and 122, and an antenna connection terminal 100.

The input terminals 111 and 112 and the output terminals 121 and 122 are connected to the RFIC 3, and the antenna connection terminal 100 is connected to the antenna 2.

The power amplifier 36 is an example of a first amplification element, and has an amplification transistor. The low noise amplifier 46 is an example of a second amplification element, and has an amplification transistor. The power amplifier 37 has an amplification transistor. The low noise amplifier 47 is an example of a third amplification element, and has an amplification transistor. The amplification transistor is, for example, a bipolar transistor such as HBT or a field effect transistor such as MOSFET.

Note that, each of the power amplifiers 36 and 37 may constitute a differential amplification type amplifier circuit. In addition, each of the power amplifiers 36 and 37 may constitute a Doherty amplifier circuit having a carrier amplifier and a peak amplifier.

The filter 66 is an example of a first filter, and has a pass band that includes the band A (first band). One end of the filter 66 is connected to the matching circuits 20T and 20R through a terminal 72D. In addition, the other end of the filter 66 is connected to the switch 61. The filter 66 is a filter for the TDD method.

The filter 67 is an example of a second filter, and has a pass band that includes the band D (second band). One end of the filter 67 is connected to the matching circuits 50T and 50R through a terminal 75D. In addition, the other end of the filter 67 is connected to the switch 61. The filter 67 is a filter for the TDD method.

In addition, the switch 61 is an example of an antenna switch, and is connected to the antenna connection terminal 100. The switch 61 switches between connection and non-connection between the antenna connection terminal 100 and the filter 66, and switches between connection and non-connection between the antenna connection terminal 100 and the filter 67.

Note that, the filters 66 and 67 may constitute a multiplexer whose common terminal is connected to the antenna connection terminal 100, and in this case, the switch 61 is not present.

The matching circuit 20T is an example of a first circuit, and is connected between an output end of the power amplifier 36 and one end of the filter 66. The matching circuit 20T has a switch 21, a capacitor 23, and an inductor 24.

The capacitor 23 is an example of a first capacitor, and is disposed in series with a first path that connects the output end of the power amplifier 36 and the filter 66. The switch 21 is an example of a first switch, the inductor 24 is an example of a first inductor, and the switch 21 and the inductor 24 are connected in series with each other.

A series connection circuit (first series connection circuit) of the switch 21 and the inductor 24 is connected in parallel to the capacitor 23.

The matching circuit 20R is an example of a second circuit, and is connected between an input end of the low noise amplifier 46 and one end of the filter 66. The matching circuit 20R has a switch 25, a capacitor 26, and an inductor 27.

The inductor 27 is an example of a second inductor, and is disposed in series with a second path that connects the input end of the low noise amplifier 46 and the filter 66. The switch 25 is an example of a second switch, the capacitor 26 is an example of a second capacitor, and the switch 25 and the capacitor 26 are connected in series with each other. A series connection circuit (second series connection circuit) of the switch 25 and the capacitor 26 is connected in parallel to the inductor 27.

The matching circuit 50T is connected between an output end of the power amplifier 37 and one end of the filter 67. The matching circuit 50T has a switch 51, a capacitor 53, and an inductor 54.

The capacitor 53 is disposed in series with a path that connects the output end of the power amplifier 37 and the filter 67. The switch 51 and the inductor 54 are connected in series with each other. A series connection circuit of the switch 51 and the inductor 54 is connected in parallel to the capacitor 53.

The matching circuit 50R is an example of a third circuit, and is connected between an input end of the low noise amplifier 47 and one end of the filter 67. The matching circuit 50R has a switch 55, a capacitor 56, and an inductor 57.

The inductor 57 is an example of a third inductor, and is disposed in series with a third path that connects the input end of the low noise amplifier 47 and the filter 67. The switch 55 is an example of a third switch, the capacitor 56 is an example of a third capacitor, and the switch 55 and the capacitor 56 are connected in series with each other. A series connection circuit (third series connection circuit) of the switch 55 and the capacitor 56 is connected in parallel to the inductor 57.

Note that, the matching circuits 20T, 20R, 50T, and 50R may be included in an IC 70D.

In addition, each of the switches 21, 25, 51, and 55 is a switch element including, for example, an FET or the like.

The band A is, for example, a band B41 (2496 to 2690 MHz) for TDD and for 4G-LTE or a band n41 (2496 to 2690 MHz) for 5G-NR. In addition, the band D is, for example, a band B40 (2300 to 2400 MHz) for TDD and for 4G-LTE or a band n40 (2300 to 2400 MHz) for 5G-NR.

According to the above circuit configuration, the radio frequency circuit 1D can transmit the transmitted signal in the band A from the input terminal 111 toward the antenna connection terminal 100. In addition, the received signal in the band A can be transmitted from the antenna connection terminal 100 toward the output terminal 121. In addition, the transmitted signal in the band D can be transmitted from the input terminal 112 toward the antenna connection terminal 100. In addition, the received signal in the band D can be transmitted from the antenna connection terminal 100 toward the output terminal 122.

Note that, the radio frequency circuit 1D according to the present modification example does not include the power amplifier 37, the low noise amplifier 47, the matching circuits 50T and 50R, the filter 67, the switch 61, the input terminal 112, and the output terminal 122.

Next, a circuit state in a case where the signal in the band A is transmitted or received will be described.

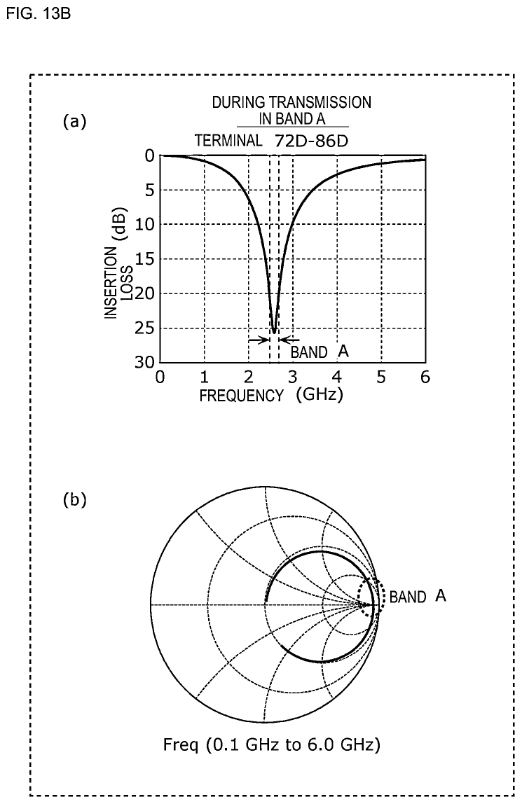

FIG. 13A is a circuit state diagram of the radio frequency circuit 1D according to Modification Example 3 in a case where the signal in the band A is transmitted. As illustrated in the drawing, in a case where the signal in the band A is transmitted, the switch 21 is in a non-conduction state and the switch 25 is in a conduction state. As a result, the transmitted signal in the band A is output from the antenna connection terminal 100 to the antenna 2 through the input terminal 111, the power amplifier 36, the terminal 76D, the capacitor 23, the terminal 72D, the filter 66, and the switch 61. At this time, since the switch 21 is in a non-conduction state, the transmitted signal in the band A does not pass through the switch 21, and a transmission loss (of, for example, approximately 0.4 dB) due to an on-resistance of the switch 21 does not occur.

In addition, at this time, since the switch 25 is in a conduction state, the matching circuit 20R constitutes an LC parallel resonance circuit in which the capacitor 26 and the inductor 27 are connected in parallel.

FIG. 13B is a graph showing (a) bandpass characteristics and (b) impedance characteristics of the matching circuit 20R of the radio frequency circuit 1D according to Modification Example 3 in a case where the signal in the band A is transmitted. (a) of FIG. 13B illustrates bandpass characteristics between terminals 72D and 86D in a case where the switch 25 is in a conduction state. In addition, (b) of FIG. 13B is a Smith chart showing an impedance of the matching circuit 20R viewed from the terminal 72D in a case where the switch 25 is in a conduction state.

As illustrated in FIG. 13B, in the matching circuit 20R, in a case where the switch 25 is in a conduction state, an LC parallel resonance point is included in the band A, and an impedance of the band A viewed from the terminal 72D is a high impedance (open state). As a result, the matching circuit 20R has characteristics of not passing (reflecting) the signal in the band A from the terminal 72D. Thus, the isolation between the transmission path and the reception path is improved, and the transmitted signal in the band A output from the power amplifier 36 is transmitted from the terminal 72D to the filter 66 without passing through the matching circuit 20R.

That is, in the radio frequency circuit 1D according to Modification Example 3, in a case where the signal in the band A is transmitted, the transmission loss due to the on-resistance of the switch 21 can be reduced, and since the transmitted signal in the band A does not leak to the reception path through the matching circuit 20R, the signal in the band A can be transmitted with a low loss.

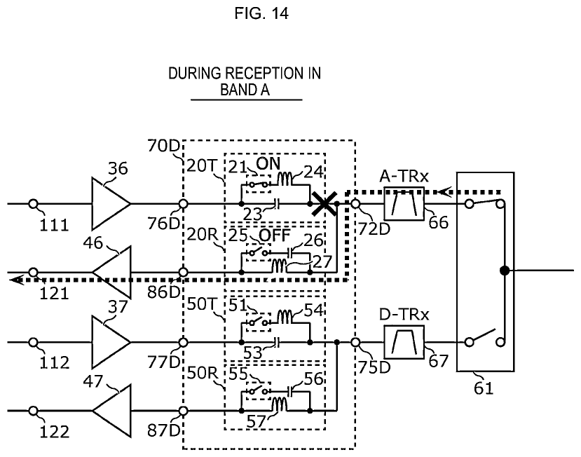

FIG. 14 is a circuit state diagram of the radio frequency circuit 1D according to Modification Example 3 in a case where the signal in the band A is received. As illustrated in the drawing, in a case where the signals in the band A are received, the switch 21 is in a conduction state and the switch 25 is in a non-conduction state. As a result, the received signal in the Band A is output from the output terminal 121 to the RFIC 3 through the antenna connection terminal 100, the switch 61, the filter 66, the terminal 72D, the inductor 27, the terminal 86D, and the low noise amplifier 46. At this time, since the switch 25 is in a non-conduction state, the received signal in the band A does not pass through the switch 25, and a transmission loss (of, for example, approximately 0.4 dB) due to an on-resistance of the switch 25 does not occur. In addition, at this time, the inductor 27 disposed in series with the reception path is suitable for impedance matching (gain matching and NF matching) between an input impedance of the low noise amplifier 46 and an output impedance of the filter 66. Note that, in a configuration in which the inductor 27 passes the received signal in the band B41 or the band n41, an inductance value of the inductor 27 is, for example, 5.6 nH.

In addition, at this time, since the switch 21 is in a conduction state, the matching circuit 20T constitutes an LC parallel resonance circuit in which the capacitor 23 and the inductor 24 are connected in parallel. The LC resonance circuit has substantially characteristics similar to the characteristics illustrated in FIG. 13B. That is, in the matching circuit 20T, in a case where the switch 21 is in a conduction state, the LC parallel resonance point is included in the band A, and the impedance of the band A viewed from the terminal 72D is a high impedance (open state). As a result, the matching circuit 20T has characteristics of not passing (reflecting) the signal in the band A from the terminal 72D. Thus, the isolation between the transmission path and the reception path is improved, and the received signal in the band A input through the antenna connection terminal 100 and the filter 66 is transmitted from the terminal 72D to the matching circuit 20R without passing through the matching circuit 20T.

That is, in the radio frequency circuit 1D according to Modification Example 3, in a case where the signal in the band A is received, the transmission loss due to the on-resistance of the switch 25 can be reduced, and since the received signal in the band A does not leak to the transmission path through the matching circuit 20T, the signal in the band A can be received with a low loss.

In the radio frequency circuit that transmits the radio frequency signal, there is a problem that the transmission loss of the radio frequency signal increases due to the on-resistance of the switch.

In contrast, according to the present modification example, it is possible to provide the radio frequency circuit 1D and the communication device 4D having the plurality of amplification elements that can transmit the radio frequency signals in the plurality of bands with a low loss.

Further, in the radio frequency circuit 1D according to Modification Example 3, since a transmission filter and a reception filter are not individually disposed and one transmission and reception filter is disposed, the size of the radio frequency circuit 1D can be reduced. In addition, since the matching circuit 20R functions as an impedance matching circuit between the low noise amplifier 46 and the filter 66 and also functions as an isolation circuit between the transmission path and the reception path, the size of the radio frequency circuit 1D can be further reduced.

Next, a circuit state in a case where the transmission of the signal in the band A and the reception of the signal in the band D are simultaneously executed will be described.

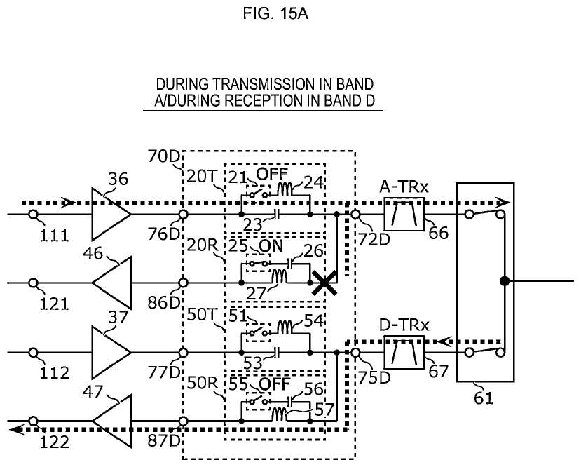

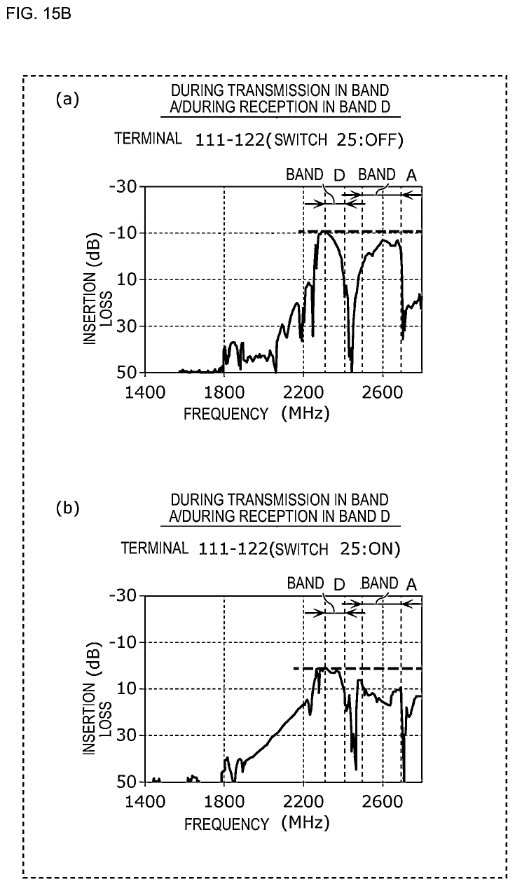

FIG. 15A is a circuit state diagram of the radio frequency circuit 1D according to Modification Example 3 in a case where the signal in the band A is transmitted and the signal in the band D is received. As illustrated in the drawing, in a case where the signal in the band A is transmitted and the signal in the band D is received, the switches 21 and 55 are in a non-conduction state, and the switch 25 is in a conduction state.

As a result, the transmitted signal in the band A is output from the antenna connection terminal 100 to the antenna 2 through the input terminal 111, the power amplifier 36, the terminal 76D, the capacitor 23, the terminal 72D, the filter 66, and the switch 61. At this time, since the switch 21 is in a non-conduction state, the transmitted signal in the band A does not pass through the switch 21, and a transmission loss (of, for example, approximately 0.4 dB) due to an on-resistance of the switch 21 does not occur.

In addition, at this time, since the switch 25 is in a conduction state, the matching circuit 20R constitutes an LC parallel resonance circuit in which the capacitor 26 and the inductor 27 are connected in parallel. As a result, the matching circuit 20R has characteristics of not passing (reflecting) the signal in the band A from the terminal 72D. Thus, the isolation between the transmission path and the reception path is improved, and the transmitted signal in the band A output from the power amplifier 36 is transmitted from the terminal 72D to the filter 66 without passing through the matching circuit 20R.

In addition, the received signal in the band D is output from the output terminal 122 to the RFIC 3 through the antenna connection terminal 100, the switch 61, the filter 67, the terminal 75D, the inductor 57, the terminal 87D, and the low noise amplifier 47. At this time, since the switch 55 is in a non-conduction state, the received signal in the band D does not pass through the switch 55, and a transmission loss (of, for example, approximately 0.4 dB) due to an on-resistance of the switch 55 does not occur. In addition, at this time, the inductor 57 disposed in series with the reception path is suitable for impedance matching (gain matching and NF matching) between an input impedance of the low noise amplifier 47 and an output impedance of the filter 67.

FIG. 15B is a graph showing cross isolation characteristics of the radio frequency circuit 1D according to Modification Example 3 in a case w the signal in the band A is transmitted and the signal in the band D is received. (a) of FIG. 15B illustrates cross isolation characteristics between the input terminal 111 and the output terminal 122 in a case where the switch 25 is in a non-conduction state (OFF). On the other hand, (b) of FIG. 15B illustrates cross isolation characteristics between the input terminal 111 and the output terminal 122 in a case where the switch 25 is in a conduction state (ON).

In a case where the switch 25 is in a non-conduction state, the transmitted signal in the band A leaks to the inductor 27 of the matching circuit 20R. At this time, when the inductor 27 and the inductor 57 are electromagnetically coupled, the inductor 27 functions as a matching element of the low noise amplifier 46, and the transmitted signal in the band A leaks to the reception path (low noise amplifier 47) in the band D through the electromagnetic coupling of the inductors 27 and 57. As a result, as illustrated in (a) of FIG. 15B, the cross isolation between the input terminal 111 and the output terminal 122 deteriorates, and reception sensitivity of the received signal in the band D detected at the output terminal 122 may deteriorate.

In contrast, in a case where the switch 25 is in a conduction state, since the matching circuit 20R is in an open state with respect to the band A and the inductor 27 does not function as the matching element of the low noise amplifier 46, the transmitted signal in the band A does not leak to the inductor 27 of the matching circuit 20R. Thus, the inductor 27 and the inductor 57 are not electromagnetically coupled, and the transmitted signal in the band A does not leak to the reception path (low noise amplifier 47) of the band D. As a result, as illustrated in (b) of FIG. 15B, the cross isolation between the input terminal 111 and the output terminal 122 is improved, and the deterioration in the reception sensitivity of the received signal in the band D detected at the output terminal 122 is suppressed.

That is, in a case where the transmission of the signal in the band A and the reception of the signal in the band D are simultaneously executed in the radio frequency circuit 1D according to Modification Example 3, the leakage of the transmitted signal in the band A to the reception path of the band D can be suppressed by bringing the switch 25 into a conduction state, and the deteriorate in the reception sensitivity of the received signal in the band D can be suppressed.

[2. Effects and the Like]

As described above, the radio frequency circuit 1 according to the present embodiment and the radio frequency circuit 1A according to Modification Example 1 include the power amplifiers 11 and 12, the transformer 14 having the input side coil 141 and the output side coil 142, the filter 62 having the pass band including the band A, the filter 63 having the pass band including the band B, the filter 64 having the pass band including the band C, the matching circuit 20 connected between one end of the output side coil 142 and the filter 62, the matching circuit 30 connected between one end of the output side coil 142 and the filter 63, and the matching circuit 40 connected between the other end of the output side coil 142 and the filter 64, and the output end of the power amplifier 11 is connected to one end of the input side coil 141, and the output end of the power amplifier 12 is connected to the other end of the input side coil 141. The matching circuit 20 has the capacitor 23 disposed in series with the first path that connects one end of the output side coil 142 and the filter 62, the switch 22 connected between the first path and the ground, and the switch 21 and the inductor 24 connected in series with each other, and the series connection circuit of the switch 21 and the inductor 24 is connected in parallel to the first path. The matching circuit 30 includes the capacitor 33 disposed in series with the second path that connects one end of the output side coil 142 and the filter 63, and the switch 31 and the inductor 34 connected in series with each other, and the series connection circuit of the switch 31 and the inductor 34 is connected in parallel to the second path. The matching circuit 40 has the switch 42 connected between the ground and the third path that connects the other end of the output side coil 142 and the filter 64.

Accordingly, the signals in the band A output from the power amplifiers 11 and 12 can be transmitted from the first path to the filter 62 without passing through the switches disposed in series in the matching circuit 20. In addition, the signals in the band B output from the power amplifiers 11 and 12 can be transmitted from the second path to the filter 63 without passing through the switches disposed in series in the matching circuit 30. In addition, the signals in the band C output from the power amplifiers 11 and 12 can be transmitted from the third path to the filter 64 without passing through the switches disposed in series in the matching circuit 40. Thus, the radio frequency circuits 1 and 1A having the plurality of amplification elements and transformers can transmit the radio frequency signals in the band A to the band C with a low loss.

In addition, for example, in the radio frequency circuit 1 and the radio frequency circuit 1A, in a case where the signal in the band A is transmitted, the switches 21 and 22 may be in a non-conduction state, the switches 31 and 42 may be in a conduction state, in a case where the signal in the band B is transmitted, the switch 31 may be in a non-conduction state, the switches 21, 22, and 42 may be in a conduction state, and in a case where the signal in the band C is transmitted, the switches 42 and 21 may be in a non-conduction state, and the switches 22 and 31 may be in a conduction state.

Accordingly, during signal transmission in the band A, since the phase at the other end of the output side coil 142 is adjusted by the matching circuit 40 and the matching circuit 30 functions as the band-elimination filter of the band A, the signal in the band A can be transmitted from the first path to the filter 62 without passing through the switches disposed in series. In addition, during signal transmission in the band B, since the phase at the other end of the output side coil 142 is adjusted by the matching circuit 40 and the matching circuit 20 functions as the band-elimination filter of the band B, the signal in the band B can be transmitted from the second path to the filter 63 without passing through the switches disposed in series. In addition, during signal transmission in the band C, since the phase at one end of the output side coil 142 is adjusted by the matching circuit 20, the signal in the band C can be transmitted from the third path to the filter 64 without passing through the switches disposed in series.

In addition, for example, in the radio frequency circuit 1 and the radio frequency circuit 1A, the capacitor 23, among the capacitor 23 and the switch 22, may be connected closer to one end of the output side coil 142.

Accordingly, the impedance at one end of the output side coil 142 shifted from the short-circuit point by the inductance component of the connection wiring that connects one end of the output side coil 142 and the switch 22 can be accurately brought into a short-circuit state.

In addition, for example, the radio frequency circuit 1 further includes the filter 65 having the pass band including the band D, and the matching circuit 50 connected between the other end of the output side coil 142 and the filter 65. The matching circuit 30 includes the switch 32 connected between the second path and the ground, the matching circuit 40 further includes the capacitor 43 disposed in series with the third path and the switch 41 and the inductor 44 connected in series with each other, the series connection circuit of the switch 41 and the inductor 44 is connected in parallel to the third path, the matching circuit 50 has the capacitor 53 disposed in series with the fourth path that connects the other end of the output side coil 142 and the filter 65, the switch 52 connected between the fourth path and the ground, and the switch 51 and the inductor 54 connected in series with each other, and the series connection circuit of the switch 51 and the inductor 54 is connected in parallel to the fourth path.

Accordingly, the signals in the band A output from the power amplifiers 11 and 12 can be transmitted from the first path to the filter 62 without passing through the switches disposed in series in the matching circuit 20. In addition, the signals in the band B output from the power amplifiers 11 and 12 can be transmitted from the second path to the filter 63 without passing through the switches disposed in series in the matching circuit 30. In addition, the signals in the band C output from the power amplifiers 11 and 12 can be transmitted from the third path to the filter 64 without passing through the switches disposed in series in the matching circuit 40. In addition, the signals in the band D output from the power amplifiers 11 and 12 can be transmitted from the fourth path to the filter 65 without passing through the switches disposed in series in the matching circuit 50. Thus, the radio frequency circuit 1 having the plurality of amplification elements and transformers can transmit the radio frequency signals in the band A to the band D with a low loss.

In addition, for example, in the radio frequency circuit 1, in a case where the signal in the band A is transmitted, the switches 21, 22, and 41 may be in a non-conduction state, and the switches 31, 32, 42, 51, and 52 may be in a conduction state, in a case where the signal in the band B is transmitted, the switches 31, 32, and 51 may be in a non-conduction state, and the switches 21, 22, 41, 42, and 52 may be in a conduction state, in a case where the signal in the band C is transmitted, the switches 21, 41, and 42 may be in a non-conduction state, and the switches 22, 31, 32, 51 and 52 may be in a conduction state, and in a case where the signal in the band D is transmitted, the switches 31, 51, and 52 may be in a non-conduction state, and the switches 21, 22, 32, 41, and 42 may be in a conduction state.

Accordingly, during signal transmission in the band A, since the phase at the other end of the output side coil 142 is adjusted by the matching circuit 40 and the matching circuits 30 and 50 function as the band-elimination filter of the band A, the signal in the band A can be transmitted from the first path to the filter 62 without passing through the switches disposed in series. In addition, during signal transmission in the band B, since the phase at the other end of the output side coil 142 is adjusted by the matching circuit 50 and the matching circuits 20 and 40 function as the band-elimination filter of the band B, the signal in the band B can be transmitted from the second path to the filter 63 without passing through the switches disposed in series. In addition, during signal transmission in the band C, since the phase at one end of the output side coil 142 is adjusted by the matching circuit 20 and the matching circuits 30 and 50 function as the band-elimination filter of the band C, the signal in the band C can be transmitted from the third path to the filter 64 without passing through the switches disposed in series. In addition, during signal transmission in the band D, since the phase at one end of the output side coil 142 is adjusted by the matching circuit 30 and the matching circuits 20 and 40 function as the band-elimination filter of the band D, the signal in the band D can be transmitted from the fourth path to the filter 65 without passing through the switches disposed in series.

In addition, for example, in the radio frequency circuit 1, the capacitor 33, among the capacitor 33 and the switch 32, may be connected closer to one end of the output side coil 142, the capacitor 43, among the capacitor 43 and the switch 42, may be connected closer to the other end of the output side coil 142, and the capacitor 53, among the capacitor 53 and the switch 52, may be connected closer to the other end of the output side coil 142.

Accordingly, the impedance at one end of the output side coil 142 shifted from the short-circuit point by the inductance component of the connection wiring that connects one end of the output side coil 142 and the switch 32 can be accurately brought into a short-circuit state. In addition, the impedance at the other end of the output side coil 142 shifted from the short-circuit point by the inductance component of the connection wiring that connects the other end of the output side coil 142 and the switch 42 can be accurately brought into a short-circuit state. In addition, the impedance at the other end of the output side coil 142 shifted from the short-circuit point by the inductance component of the connection wiring that connects the other end of the output side coil 142 and the switch 52 can be accurately brought into a short-circuit state.

In addition, for example, in the radio frequency circuit 1, the frequencies of the band A and the band B do not overlap each other, and the frequencies of the band C and the band D do not overlap each other.

Accordingly, the isolation between the first path and the second path connected to one end of the output side coil 142 is improved, and the isolation between the third path and the fourth path connected to the other end of the output side coil 142 is improved.

In addition, for example, the radio frequency circuit 1 further includes the module board 90 having the principal surfaces 90a and 90b facing each other. The power amplifiers 11 and 12 and the inductors 24, 34, 44, and 54 are disposed on the principal surface 90a, and the semiconductor IC 81 including the switches 21, 31, 41, and 51 may be disposed on the principal surface 90b.

Accordingly, since the circuit components constituting the radio frequency circuit 1 are disposed on the principal surfaces 90a and 90b in a distribution manner, the size of the radio frequency circuit 1 can be reduced.

For example, in the radio frequency circuit 1, in a case where the module board 90 is viewed in plan view, the inductors 24, 34, 44, and 54 and the semiconductor IC 81 may at least partially overlap each other.

Accordingly, the wiring that connects the inductor 24 and the switch 21 in the matching circuit 20 can be shortened. In addition, the wiring that connects the inductor 34 and the switch 31 in the matching circuit 30 can be shortened. In addition, the wiring that connects the inductor 44 and the switch 41 in the matching circuit 40 can be shortened. In addition, the wiring that connects the inductor 54 and the switch 51 in the matching circuit 50 can be shortened. Thus, the size and the loss of the radio frequency circuit 1 can be reduced.

In addition, for example, in the radio frequency circuit 1, the magnetic flux direction of the inductor 24 and the magnetic flux direction of the inductor 44 may be orthogonal to each other, and the magnetic flux direction of the inductor 34 and the magnetic flux direction of the inductor 54 may be orthogonal to each other.

Accordingly, even in a case where the frequencies of the band A and the band C partially overlap or are close to each other, signal leakage through the magnetic coupling of the inductors 24 and 44 can be suppressed. In addition, even in a case where the frequencies of the band B and the band D partially overlap or are close to each other, signal leakage through the magnetic coupling of the inductors 34 and 54 can be suppressed.

In addition, for example, the radio frequency circuit 1C further includes the module board 90 having the principal surfaces facing each other. The power amplifiers 11 and 12, the inductors 24, 34, 44 and 54, and the semiconductor IC 81 including the switches 21, 31, 41, and 51 are disposed on the principal surfaces, and each of the inductors 24, 34, 44, and 54 may include the bonding wire.

Accordingly, a degree of freedom in disposing the inductors 24, 34, 44, and 54 is ensured, and the size of the radio frequency circuit 1C can be reduced.

In addition, the radio frequency circuit 1B according to Modification Example 2 of the present embodiment includes the power amplifiers 15, 16, 17, and 18, the transformer 68 having the first input side coil and the first output side coil, the transformer 69 having the second input side coil and the second output side coil, the filter 62 having the pass band including the band A, the filter 63 having the pass band including the band B, the filter 64 having the pass band including the band C, the filter 65 having the pass band including the band D, the matching circuit 20 connected between one end of the first output side coil and the filter 62, the matching circuit 30 connected between one end of the first output side coil and the filter 63, the matching circuit 40 connected between one end of the second output side coil and the filter 64, and the matching circuit 50 connected between one end of the second output side coil and the filter 65. The output end of the power amplifier 15 is connected to one end of the first input side coil, the output end of the power amplifier 16 is connected to the other end of the first input side coil, the output end of the power amplifier 17 is connected to one end of the second input side coil, the output end of the power amplifier 18 is connected to the other end of the second input side coil, and the other end of the first output side coil is connected to the other end of the second output side coil. The matching circuit 20 has the capacitor 23 disposed in series with the first path that connects one end of the first output side coil and the filter 62, the switch 22 connected between the first path and the ground, and the switch 21 and the inductor 24 connected in series with each other, and the series connection circuit of the switch 21 and the inductor 24 is connected in parallel to the first path. The matching circuit 30 has the capacitor 33 disposed in series with the second path that connects one end of the first output side coil and the filter 63, the switch 32 connected between the second path and the ground, and the switch 31 and the inductor 34 connected in series with each other, and the series connection circuit of the switch 31 and the inductor 34 is connected in parallel to the second path. The matching circuit 40 has the capacitor 43 disposed in series with the third path that connects one end of the second output side coil and the filter 64, the switch 42 connected between the third path and the ground, and the switch 41 and the inductor 44 connected in series with each other, and the series connection circuit of the switch 41 and the inductor 44 is connected in parallel to the third path. The matching circuit 50 has the capacitor 53 disposed in series with the fourth path that connects one end of the second output side coil and the filter 65, the switch 52 connected between the fourth path and the ground, and the switch 51 and the inductor 54 connected in series with each other, and the series connection circuit of the switch 51 and the inductor 54 is connected in parallel to the fourth path.

Accordingly, the signals in the band A output from the power amplifiers 15 to 18 are transmitted from the first path to the filter 62 without passing through the switches disposed in series. In addition, the signals in the band B output from the power amplifiers 15 to 18 are transmitted from the second path to the filter 63 without passing through the switches disposed in series. In addition, the signals in the band C output from the power amplifiers 15 to 18 are transmitted from the third path to the filter 64 without passing through the switches disposed in series. In addition, the signals in the band D output from the power amplifiers 15 to 18 are transmitted from the fourth path to the filter 65 without passing through the switches disposed in series. Thus, the radio frequency circuit 1B can transmit the radio frequency signals in the band A to the band D with a low loss.

In addition, the radio frequency circuit 1D according to Modification Example 3 of the present embodiment includes the power amplifier 36 and the low noise amplifier 46, the filter 66 having the pass band including the band A, the matching circuit 20T connected between the output end of the power amplifier 36 and one end of the filter 66, and the matching circuit 20R connected between the input end of the low noise amplifier 46 and one end of the filter 66. The matching circuit 20T includes the capacitor 23 disposed in series with the first path that connects the output end of the power amplifier 36 and the filter 66, and the first series connection circuit that includes the switch 21 and the inductor 24 connected in series with each other and is connected in parallel to the capacitor 23. The matching circuit 20R includes the inductor 27 disposed in series with the second path that connects the input end of the low noise amplifier 46 and the filter 66, and the second series connection circuit that includes the switch 25 and the capacitor 26 connected in series with each other and is connected in parallel to the inductor 27.

Accordingly, the switch 21 is brought into a non-conduction state, and thus, the transmission loss due to the on-resistance of the switch 21 can be reduced during transmission in the band A. In addition, the switch 25 is brought into a conduction state, and thus, the matching circuit 20R can function as the LC parallel resonance circuit and the signal in the band A cannot pass through the matching circuit 20R. Thus, in a case where the signal in the band A is transmitted, the transmission loss due to the on-resistance of the switch 21 can be reduced, and since the transmitted signal in the band A does not leak to the reception path through the matching circuit 20R, the signal in the band A can be transmitted with a low loss. In addition, the switch 25 is brought into a non-conduction state, and thus, the transmission loss due to the on-resistance of the switch 25 can be reduced during reception in the band A. The impedance matching between the low noise amplifier 46 and the filter 66 can be achieved by the inductor 27. In addition, the switch 21 is brought into a conduction state, and thus, the matching circuit 20T can function as the LC parallel resonance circuit and the signal in the band A cannot pass through the matching circuit 20T. Thus, in a case where the signal in the band A is received, the transmission loss due to the on-resistance of the switch 25 can be reduced, and since the received transmitted signal in the band A does not leak to the transmission path through the matching circuit 20T, the signal in the band A can be received with a low loss.

Thus, it is possible to provide the radio frequency circuit 1D having the plurality of amplification elements that can transmit the radio frequency signals in the plurality of bands with a low loss.

For example, in the radio frequency circuit 1D, in a case where the signal in the band A is transmitted, the switch 21 is in a non-conduction state, and the switch 25 is in a conduction state. On the other hand, in a case where the signal in the band A is received, the switch 21 may be in a conduction state, and the switch 25 may be in a non-conduction state.

In addition, for example, in the radio frequency circuit 1D, the power amplifier 36 may be a power amplifier, the low noise amplifier 46 may be a low noise amplifier, and the filter 66 may be a filter for TDD.

Accordingly, since the radio frequency circuit 1D does not individually have a transmission filter and a reception filter for the band A, the size of the radio frequency circuit 1D can be reduced.

In addition, for example, the radio frequency circuit 1D further includes the low noise amplifier 47, the filter 67 having the pass band including the band D, and the matching circuit 50R connected between the input end of the low noise amplifier 47 and the filter 67. The matching circuit 50R includes the inductor 57 disposed in series with the third path that connects the input end of the low noise amplifier 47 and the filter 67, and the third series connection circuit that includes the switch 55 and the capacitor 56 connected in series with each other and is connected in parallel to the inductor 57.

Accordingly, in a case where the switch 25 is in a conduction state, since the matching circuit 20R is in an open state with respect to the band A and the inductor 27 does not function as the matching element of the low noise amplifier 46, the transmitted signal in the band A does not leak to the inductor 27 of the matching circuit 20R. Thus, the inductor 27 and the inductor 57 are not electromagnetically coupled, and the transmitted signal in the band A does not leak to the reception path (low noise amplifier 47) of the band D. As a result, the cross isolation between the transmission path of the band A and the reception path of the band D is improved, and the deterioration in the reception sensitivity of the received signal in the band D is suppressed. That is, in a case where the transmission of the signal in the band A and the reception of the signal in the band D are simultaneously executed, the leakage of the transmitted signal in the band A to the reception path of the band D can be suppressed by bringing the switch 25 into a conduction state, and the deteriorate in the reception sensitivity of the received signal in the band D can be suppressed.

For example, in the radio frequency circuit 1D, in a case where the transmission of the signal in the band A and the reception of the signal in the band D are simultaneously executed, the switch 21 may be in a non-conduction state, the switch 25 may be in a conduction state, and the switch 55 may be in a non-conduction state.

In addition, for example, in the radio frequency circuit 1D, the low noise amplifier 47 may be a low noise amplifier, and the filter 67 may be a filter for TDD.

Accordingly, since the radio frequency circuit 1D does not individually have a transmission filter and a reception filter for the band D, the size of the radio frequency circuit 1D can be reduced.

In addition, the communication device 4 according to the present embodiment includes the RFIC 3 that processes the radio frequency signal, and the radio frequency circuit 1 that transmits the radio frequency signal between the RFIC 3 and the antenna 2.

Accordingly, the effect of the radio frequency circuit 1 can be realized by the communication device 4.

### Other Embodiments and the Like

Although the radio frequency circuit and the communication device according to the embodiment of the present disclosure have been described above in conjunction with the embodiment, the example, and the modification examples, the radio frequency circuit and the communication device according to the present disclosure are not limited to the above embodiment, example, and modification examples. Another embodiment realized by combining any constituent elements in the above embodiment, example, and modification examples, modification examples obtained by applying various modifications that can be thought of by a person skilled in the art to the above embodiment, example, and modification examples without departing from the gist of the present disclosure, and various types of equipment having the above radio frequency circuit and communication device incorporated therein are included in the present disclosure.

For example, in the radio frequency circuits according to the above embodiment and modification examples, although each of the matching circuits 20 to 50 has the capacitor, the inductor, and the two switches, the present disclosure is not limited thereto. Each of the matching circuits 20 to 50 may have a circuit element in addition to the capacitor, the inductor, and the two switches.

In addition, for example, in the radio frequency circuit and the communication device according to the above embodiment, example, and modification examples, another circuit element, wiring, and the like may be inserted between paths that connect each circuit element and a signal path disclosed in the drawings.

### INDUSTRIAL APPLICABILITY

The present disclosure can be widely used in communication equipment, such as a mobile phone, as a radio frequency circuit disposed at a front end portion corresponding to a multiband.

### REFERENCE SIGNS LIST

1, 1A, 1B, 1C, 1D radio frequency circuit
2 antenna
3 RF signal processing circuit (RFIC)
4, 4D communication device
10 preamplifier
11, 12, 15, 16, 17, 18, 36, 37 power amplifier
13, 14, 68, 69 transformer
20, 20R, 20T, 30, 40, 45, 50, 50R, 50T matching circuit
21, 22, 25, 31, 32, 41, 42, 51, 52, 55, 60, 61 switch
23, 26, 33, 43, 53, 56 capacitor
24, 27, 34, 44, 54, 57 inductor
46, 47 low noise amplifier
62, 63, 64, 65, 66, 67 filter
70, 70D IC
72, 72D, 73, 74, 75, 75D, 76, 76D, 77, 77D, 78, 86D, 87D terminal
80, 81 semiconductor IC
90 module board
90a, 90b principal surface
100 antenna connection terminal
110, 111, 112 input terminal
121, 122 output terminals
131 primary side coil
132 secondary side coil
141 input side coil
142 output side coil

1. A radio frequency circuit comprising:
a first amplification element and a second amplification element;
a transformer having an input side coil and an output side coil;
a first filter having a pass band including a first band;
a second filter having a pass band including a second band;
a third filter having a pass band including a third band;
a first circuit connected between one end of the output side coil and the first filter;
a second circuit connected between the one end of the output side coil and the second filter; and
a third circuit connected between another end of the output side coil and the third filter,
wherein an output end of the first amplification element is connected to one end of the input side coil,
an output end of the second amplification element is connected to another end of the input side coil,
the first circuit has
a first capacitor disposed in series with a first path connecting the one end of the output side coil and the first filter,
a first switch connected between the first path and a ground, and
a second switch and a first inductor connected in series with each other,
a series connection circuit of the second switch and the first inductor is connected in parallel to the first path,
the second circuit has
a second capacitor disposed in series with a second path connecting the one end of the output side coil and the second filter, and
a third switch and a second inductor connected in series with each other,
a series connection circuit of the third switch and the second inductor is connected in parallel to the second path, and
the third circuit has a fourth switch connected between a ground and a third path connecting the other end of the output side coil and the third filter.

2. The radio frequency circuit according to claim 1,
wherein, in a case where a signal in the first band is transmitted, the first switch and the second switch are in a non-conduction state, and the third switch and the fourth switch are in a conduction state,
in a case where a signal in the second band is transmitted, the third switch is in a non-conduction state, and the first switch, the second switch, and the fourth switch are in a conduction state, and
in a case where a signal in the third band is transmitted, the fourth switch and the second switch are in a non-conduction state, and the first switch and the third switch are in a conduction state.

3. The radio frequency circuit according to claim 2, wherein the first capacitor, among the first capacitor and the first switch, is connected close to the one end of the output side coil.

4. The radio frequency circuit according to claim 3, further comprising:
a fourth filter having a pass band including a fourth band; and
a fourth circuit connected between the other end of the output side coil and the fourth filter,
wherein the second circuit further has a fifth switch connected between the second path and the ground,
the third circuit further has
a third capacitor disposed in series with the third path, and
a sixth switch and a third inductor connected in series with each other,
a series connection circuit of the sixth switch and the third inductor is connected in parallel to the third path,
the fourth circuit has
a fourth capacitor disposed in series with a fourth path connecting the other end of the output side coil and the fourth filter,
a seventh switch connected between the fourth path and the ground, and
an eighth switch and a fourth inductor connected in series with each other, and
a series connection circuit of the eighth switch and the fourth inductor is connected in parallel to the fourth path.

5. The radio frequency circuit according to claim 4,
wherein, in a case where a signal in the first band is transmitted, the first switch, the second switch, and the sixth switch are in a non-conduction state, and the third switch, the fourth switch, the fifth switch, the seventh switch, and the eighth switch are in a conduction state,
in a case where a signal in the second band is transmitted, the third switch, the fifth switch, and the eighth switch are in a non-conduction state, and the first switch, the second switch, the fourth switch, the sixth switch, and the seventh switch are in a conduction state,
in a case where a signal in the third band is transmitted, the second switch, the fourth switch, and the sixth switch are in a non-conduction state, and the first switch, the third switch, the fifth switch, the seventh switch, and the eighth switch are in a conduction state, and
in a case where a signal in the fourth band is transmitted, the third switch, the seventh switch, and the eighth switch are in a non-conduction state, and the first switch, the second switch, the fourth switch, the fifth switch, and the sixth switch are in a conduction state.

6. The radio frequency circuit according to claim 5,
wherein the second capacitor, among the second capacitor and the fifth switch, is connected close to the one end of the output side coil,
the third capacitor, among the third capacitor and the fourth switch, is connected close to the other end of the output side coil, and
the fourth capacitor, among the fourth capacitor and the seventh switch, is connected close to the other end of the output side coil.

7. The radio frequency circuit according to claim 6,
wherein frequencies of the first band and the second band do not overlap, and
frequencies of the third band and the fourth band do not overlap.

8. The radio frequency circuit according to claim 7, further comprising:
a module board having a first principal surface and a second principal surface facing each other,
wherein the first amplification element, the second amplification element, the first inductor, the second inductor, the third inductor, and the fourth inductor are disposed on the first principal surface, and
a semiconductor IC including the second switch, the third switch, the sixth switch, and the eighth switch is disposed on the second principal surface.

9. The radio frequency circuit according to claim 8, wherein, in a case where the module board is viewed in plan view, the first inductor, the second inductor, the third inductor, the fourth inductor, and the semiconductor IC at least partially overlap.

10. The radio frequency circuit according to claim 9,
wherein a magnetic flux direction of the first inductor and a magnetic flux direction of the third inductor are orthogonal to each other, and
a magnetic flux direction of the second inductor and a magnetic flux direction of the fourth inductor are orthogonal to each other.

11. The radio frequency circuit according to claim 7, further comprising:
a module board having principal surfaces facing each other,
wherein the first amplification element, the second amplification element, the first inductor, the second inductor, the third inductor, the fourth inductor, and a semiconductor IC including the second switch, the third switch, the sixth switch, and the eighth switch are disposed on the principal surface, and
each of the first inductor, the second inductor, the third inductor, and the fourth inductor includes a bonding wire.

12. A radio frequency circuit comprising:
a first amplification element, a second amplification element, a third amplification element, and a fourth amplification element;
a first transformer having a first input side coil and a first output side coil;
a second transformer having a second input side coil and a second output side coil;
a first filter having a pass band including a first band;
a second filter having a pass band including a second band;
a third filter having a pass band including a third band;
a fourth filter having a pass band including a fourth band;
a first circuit connected between one end of the first output side coil and the first filter;
a second circuit connected between the one end of the first output side coil and the second filter;
a third circuit connected between one end of the second output side coil and the third filter; and
a fourth circuit connected between the one end of the second output side coil and the fourth filter,
wherein an output end of the first amplification element is connected to one end of the first input side coil,
an output end of the second amplification element is connected to another end of the first input side coil,
an output end of the third amplification element is connected to one end of the second input side coil,
an output end of the fourth amplification element is connected to another end of the second input side coil,
another end of the first output side coil is connected to another end of the second output side coil,
the first circuit has
a first capacitor disposed in series with a first path connecting the one end of the first output side coil and the first filter,
a first switch connected between the first path and a ground, and
a second switch and a first inductor connected in series with each other,
a series connection circuit of the second switch and the first inductor is connected in parallel to the first path,
the second circuit has
a second capacitor disposed in series with a second path connecting the one end of the first output side coil and the second filter,
a fifth switch connected between the second path and the ground, and
a third switch and a second inductor connected in series with each other,
a series connection circuit of the third switch and the second inductor is connected in parallel to the second path,
the third circuit has
a third capacitor disposed in series with a third path connecting the one end of the second output side coil and the third filter,
a fourth switch connected between the third path and the ground, and
a sixth switch and a third inductor connected in series with each other,
a series connection circuit of the sixth switch and the third inductor is connected in parallel to the third path,
the fourth circuit has
a fourth capacitor disposed in series with a fourth path connecting the one end of the second output side coil and the fourth filter,
a seventh switch connected between the fourth path and the ground, and
an eighth switch and a fourth inductor connected in series with each other, and
a series connection circuit of the eighth switch and the fourth inductor is connected in parallel to the fourth path.

13. A radio frequency circuit comprising:
a first amplification element and a second amplification element;
a first filter having a pass band including a first band;
a first circuit connected between an output end of the first amplification element and one end of the first filter; and
a second circuit connected between an input end of the second amplification element and the one end of the first filter,
wherein the first circuit has
a first capacitor disposed in series with a first path connecting the output end of the first amplification element and the first filter, and
a first series connection circuit that includes a first switch and a first inductor connected in series with each other, and is connected in parallel to the first capacitor, and
the second circuit has
a second inductor disposed in series with a second path connecting the input end of the second amplification element and the first filter, and
a second series connection circuit that includes a second switch and a second capacitor connected in series with each other, and is connected in parallel to the second inductor.

14. The radio frequency circuit according to claim 13,
wherein, in a case where a signal in the first band is transmitted, the first switch is in a non-conduction state, and the second switch is in a conduction state, and
in a case where the signal in the first band is received, the first switch is in a conduction state, and the second switch is in a non-conduction state.

15. The radio frequency circuit according to claim 14,
wherein the first amplification element is a power amplifier,
the second amplification element is a low noise amplifier, and
the first filter is a filter for time division duplex.

16. The radio frequency circuit according to claim 15, further comprising:
a third amplification element;
a second filter having a pass band including a second band; and
a third circuit connected between an input end of the third amplification element and the second filter,
wherein the third circuit has
a third inductor disposed in series with a third path connecting the input end of the third amplification element and the second filter, and
a third series connection circuit that includes a third switch and a third capacitor connected in series with each other, and is connected in parallel to the third inductor.

17. The radio frequency circuit according to claim 16, wherein, in a case where transmission of a signal in the first band and reception of a signal in the second band are simultaneously executed, the first switch is in a non-conduction state, the second switch is in a conduction state, and the third switch is in a non-conduction state.

18. The radio frequency circuit according to claim 16,
wherein the third amplification element is a low noise amplifier, and
the second filter is a filter for time division duplex.

19. A communication device comprising:
a signal processing circuit configured to process a radio frequency signal; and
the radio frequency circuit according to claim 1, which is configured to transmit the radio frequency signal between the signal processing circuit and an antenna.

20. A communication device comprising:
a signal processing circuit configured to process a radio frequency signal; and
the radio frequency circuit according to claim 12, which is configured to transmit the radio frequency signal between the signal processing circuit and an antenna.
